(19) United States
(12) Patent Application Publication
(10) Pub. No.: US 2014/0302310 A1
(43) Pub. Date: Oct. 9, 2014

(54) AMORPHOUS MULTI-COMPONENT METAL/METAL OXIDE NANOLAMINATE METAMATERIALS AND DEVICES BASED THEREON

(71) Applicants: E. William Cowell, III, Corvallis, OR (US); John F. Wager, Corvallis, OR (US); Douglas A. Keszler, Corvallis, OR (US); Nicholas A. Kuhta, Corvallis, OR (US); Christopher C. Knutson, Corvallis, OR (US)

(72) Inventors: E. William Cowell, III, Corvallis, OR (US); John F. Wager, Corvallis, OR (US); Douglas A. Keszler, Corvallis, OR (US); Nicholas A. Kuhta, Corvallis, OR (US); Christopher C. Knutson, Corvallis, OR (US)

(73) Assignee: The State of Oregon Acting by and Through the State Board of Higher Education on Behalf of Or..., Corvallis, OR (US)

(21) Appl. No.: 14/004,736

(22) PCT Filed: Mar. 19, 2012
(86) PCT No.: PCT/US12/29684

§ 371 Date: Nov. 22, 2013

Related U.S. Application Data
(60) Provisional application No. 61/454,231, filed on Mar. 18, 2011.

(51) Int. Cl. H01L 29/15

(52) U.S. Cl. CPC H01L 29/154
USPC 428/336; 428/457; 428/469; 428/472.2; 428/472

(57) ABSTRACT

Nanolaminates comprised of alternating layers of amorphous, multi-component metallic films (AMMFs) and metal oxide films are disclosed as metamaterials whose physical properties can be engineered to customize the resulting electrical, average dielectric, and thermal properties. In certain configurations using AMMFs, the construct may be an optical or an electronic element, such a metal-insulator-metal (MIM) diode, for example.

### RELATED APPLICATIONS

This application claims the benefit of priority of U.S. Provisional Application No. 61/454,231, filed on Mar. 18, 2011, the entire contents of which application(s) are incorporated herein by reference.

### ACKNOWLEDGMENT OF GOVERNMENT SUPPORT

This invention was made with government support under W909MY-06-C-0038 and W911NF-07-2-0083 awarded by U.S. Army Research Laboratory and under CHE-0847970 awarded by the National Science Foundation. The government has certain rights in the invention.

### BACKGROUND

Diodes may be utilized in integrated circuitry for numerous applications. For instance, diodes may be utilized for regulating current flow, and/or may be utilized as select devices for selectively accessing components of the integrated circuitry. A class of diodes that is of particular interest are so called metal-insulator-metal (MIM) diodes, which are diodes having one or more electrically insulative materials sandwiched between a pair of electrically conductive electrodes. (The electrodes may be defined to be a first electrode and a second electrode. The diodes may be considered to control electron flow from the first electrode to the second electrode, and to impede electron flow from the second electrode to the first electrode. Since current flow is defined to be in the opposite direction to electron flow; the diodes may also be considered to control current flow from the second electrode to the first electrode, and from the first electrode to the second electrode.)

However, effectively controlling quantum mechanical tunneling through an ultrathin dielectric represents a fundamental materials challenge in the quest for high-performance MIM diodes. Such diodes may form the basis for alternative approaches to conventional thin-film transistor technologies for large-area information displays, various types of hot electron transistors, ultrahigh speed discrete or antenna coupled detectors, and optical rectennas. To date, MIM diodes have invariably exhibited poor yield and performance due in large extent to the roughness of the surface of the crystalline metal film, which is often larger than the thickness of the MIM insulator. As a result, the electric field across a MIM device can be highly nonuniform, making the control of quantum mechanical tunneling problematic.

In addition to materials for use in electrical devices such as diodes, materials exhibiting anomalous dispersion hold the promise to yield optical devices with superior performance; however, the majority of extant optical metamaterials require either high powered light sources or material patterning to allow for the measurement of negative refractive index or hyperbolic dispersion, primarily due to the high loss nature of the constituent materials, coupled with the thicknesses needed to achieve homogonous films. For example, current bilayer thicknesses put a lower limit of 570 nm on the wavelengths where effective medium behavior has been observed. Also inherent in many such prototypical materials is a difficulty to effectively manufacture such structures. Still further, any number of applications would be advanced by an ability to manage thermal device behavior through the use of materials which exhibit anisotropic thermal conductivity.

Accordingly, it would be an advancement in the art to provide a material platform that exhibits ease of manufacture, the precise control of material properties, and the ability to measure relevant material characteristics for a variety of applications including electronic and optical, as well as those which would benefit from directional management of thermal conductivity.

### SUMMARY

Nanolaminates comprised of alternating layers of amorphous, multi-component metallic films (AMMFs) and metal oxide films are disclosed as metamaterials whose physical properties can be engineered to customize the resulting electrical, average dielectric, and/or thermal properties. In certain configurations using AMMFs, the construct may be an optical element, an electronic device, or a structure exhibiting thermal management via anisotropic thermal conductivity. As used herein, a metamaterial may be a laminate comprised of thin (e.g., <100 nm) bilayers made with physically and electronically dissimilar materials, with the thickness of the layer tailored to the particular device application. The macroscopic properties (e.g., dielectric constant and thermal conductivity) of the metamaterials can be engineered to values that are not possible in homogeneous bulk materials. Exemplary technology applications enabled by the metamaterials and processes described herein include, without limitation, ones suited for use in electronic devices, optical devices, and/or anisotropic thermal conduction applications. For example, the potential applications of optical amorphous metamaterials include lenses with sub-wavelength resolution, optical filters, absorber materials for solar cells, laser gyroscopes/waveguides, stealth coatings, custom/anisotropic indices of refraction coatings, and optically graded materials. In the electronic device regime, exemplary applications of AMMFs may include, without limitation, vertical transport thin-film transistors (VTTFTs), and metal-insulator-metal (MIM) tunnel diodes. Potential applications of anisotropic thermally conducting metamaterials may include without limitation heat shielding coatings, window heat shielding coatings, and other heat shielding materials, for example. In one of its aspects, the present disclosure pertains to the use of amorphous metal multi-component films comprising combinations of metallic elements with varying atomic radii causing a deep eutectic point and or varying enthalpies of oxidation for metal layers in the realization of nanolaminate metamaterials that exhibit optical effective medium behavior, anisotropic thermal conductivity, and/or provide high-performance electrical conductors in electronic device applications.

As to the optical metamaterials of the present disclosure, such materials include ones in which the macroscopic dielectric properties of the metamaterial are controlled by an averaging of the distinct, bulk material dielectric properties. Effective medium theory predicts the averaging of dielectric behavior between the distinct layers of the nanolaminate when the layers are significantly thinner (i.e. less than 25 times thinner) than the wavelength of incident light (quasi-static approximation). The result of effective medium averaging is two effective anisotropic dielectric constants, ∈_{z} and ∈_{xy}, where z is the direction normal to the layer boundaries. When the effective anisotropic dielectric constants have opposite signs metamaterials have hyperbolic dispersion, and negative refraction may occur for specifically polarized light. ∈_{z}<0 and ∈_{xy}>0 are the necessary conditions for exhibiting negative refraction, whereas ∈_{z}>0 and ∈_{xy}<0 produce positive refraction with hyperbolic dispersion. The ability to model metamaterial optical properties based on measurement of the bulk optical properties provides a path towards realization of both types of hyperbolic dispersion.

In conventional materials, the Poynting vector (direction of energy) and the momentum vector (wavefront direction) are typically coincident. A consequence of anisotropic dielectric constants (i.e. Re(∈_{z}) and Re(∈_{xy}) having opposite signs) is a wave propagating in an effective medium having a Poynting vector and momentum vector which point in different directions (i.e. are not coincident). With the exemplary materials of the present disclosure, the ability to leverage effective medium theory towards the prediction of metamaterial optical dielectric behavior opens the door for dispersion engineering, as bulk dielectric constants and individual layer thicknesses are the only required input parameters. The bulk optical measurements may be easily attained via scanning spectroscopic ellipsometry, while the thickness values may be attained via straightforward growth rate characterizations. The ellipsometry reflectance data may also be used as confirmation of metal/dielectric ratio as the model to measured data alignment (measured as normalized error) diverges quickly as the ratio of metal to dielectric is changed in the model from the known value.

The ultra-thin (e.g. <20 nm) thicknesses of AMMFs that may be realized via simple magnetron sputtering will allow for transmission measurements without patterning, thereby simplifying the fabrication of optical metamaterials. Additionally, the ultra-thin nature of our bilayers attained by employing amorphous thin films, have the ability to satisfy the quasi-static criteria down to 250 nm (or shorter) light. Therefore, the use of amorphous metal and amorphous oxide thin films shows promise in extending the observable, unpatterned, quasistatic effective medium regime to wavelengths below those reported to date. However, interfacial scattering between constituent layers can contribute to increased optical loss in laminate structures. Nanometer-scale interfacial roughness can negatively impact optical transmission as the employed optical wavelengths become shorter. The methods of the present disclosure for depositing ultra-thin/ultra-smooth AMMFs at room temperature via sputtering that remain amorphous (and smooth) with heated processing lends itself to applications as optical metamaterial. The resulting interfaces created in the amorphous metal/oxide nanolaminates are atomically smooth and stoichiometrically controllable to sub-nanometer distances. Thus, the amorphous nature of the films and smooth interfaces between the films reduce interfacial scatterings of light through the metamaterials.

In another of its aspects, the present disclosure relates to AMMFs having anisotropic thermal conductivity. Due to their amorphous nature, amorphous metals do not possess high thermal conductivity as deposited. As the amorphous metals are heated, oxidation and crystallization phenomena occur. The ability to selectively react and crystallize the elemental components of the amorphous metal layers in a nanolaminate while maintaining the amorphous nature and the atomically smooth interfacial morphologies of the interleaving oxide layers allows for the creation of a thermally anisotropic material. This ability to selectively crystallize as deposited AMMFs relative to amorphous oxide layers, thereby increasing the metal layer thermal conductivity, allows for the realization of anisotropic thermal conduction metamaterials. The resulting thermal conductivity in the plane of the laminate layers will be high relative to the thermal conductivity perpendicular to the laminate layers due to the enhanced thermal conductivity of the spatially-confined, polycrystalline metal.

Thus, in one of its aspects the present disclosure provides an amorphous multi-component metallic nanolaminate, comprising a plurality of film layers disposed in continuity with one another and having a first film layer comprising an amorphous multi-component metal and having a second film layer comprising a dielectric. Without regard to the particular stoichiometry, the amorphous metal may include ZrCuAlNi, TiAl, or combinations thereof, and may include at least one element selected from Groups IV, V, VI, X, Al, Mg, Sn, or Zn. Particular exemplary stoichiometries include Zr₅₅Cu₃₀Al₁₀Ni₅ and TiAl₃. The second film layer may include an amorphous oxide, Al₂O₃, aluminum phosphate, silicon dioxide, a metal halide, calcium fluoride, zirconium oxide, hafnium dioxide, titanium dioxide, SnO2, ZnO, or combinations thereof. The effective dielectric constant in the plane of the plurality of layers may have the opposite sign to that of the effective dielectric constant perpendicular to the plane of plurality of the layers. In addition, the plurality of film layers may have a positive or a negative index of refraction, and/or a hyperbolic dispersion.

Disclosed herein is an electronic device structure comprising (a) a first metal layer; (b) a second metal layer; and (c) and at least one insulator layer located between the first metal layer and the second metal layer, wherein at least one of the metal layers comprises an amorphous multi-component metallic film. Also disclosed herein is an electronic device structure comprising (a) at least one electrode comprising an amorphous multi-component metallic film; and (b) at least one other substrate positioned adjacent to amorphous multi-component film.

Processes for making electronic device structures are also disclosed herein. For example, one such process is a method for making an electronic device structure comprising: forming an amorphous multi-component metallic film electrode on a first substrate; and depositing at least one layer on the multi-component metallic film electrode.

Another process is a method for making a metal-insulator-metal diode comprising: forming a first electrode on a first substrate wherein the first electrode defines a first surface facing the first substrate and an opposing second surface; forming an insulator layer on the second surface of the first electrode, wherein the insulator layer defines a first surface facing the first electrode and an opposing second surface; and forming a second electrode on the second surface of the insulator layer, wherein at least one of the electrodes comprises an amorphous multi-component metallic film.

The foregoing is disclosed in the following detailed description, which proceeds with reference to the accompanying figures.

### BRIEF DESCRIPTION OF THE DRAWINGS

FIG. 1: Energy band diagram of a MIMIM HOT.

FIG. 2: Physical structure of a MIM tunnel diode as disclosed herein.

FIG. 3: Atomic force micrograph image of an AMMF (Zr₅₅Cu₃₀Al₁₀Ni₅ composition) deposited via RF magnetron sputtering onto a silicon substrate at room temperature.

FIG. 4: Atomic force micrograph image of an AMMF (Zr₅₅Cu₃₀Al₁₀Ni₅ composition) deposited via RF magnetron sputtering onto a <100> silicon substrate at room temperature and subsequently subjected to a 350° C. anneal in air for 1 hour.

FIG. 5: XRD patterns of two AMMFs (Zr₅₅Cu₃₀Al₁₀Ni₅ composition) deposited via RF magnetron sputtering onto a <100> silicon substrate at room temperature. The two patterns are from an as-deposited film, and after a 300° C. anneal in air for 1 hour.

FIG. 6: I vs V Curve (bi-directional) of Tunnel diode created with AMMF (Zr₅₅Cu₃₀Al₁₀Ni₅ composition). Lack of hysteresis and low sub-turn on current (22 pA average between 0 and 2.5 V) illustrate interface quality between AMMF and insulator.

FIG. 7: I vs V Curve (bi-directional) of Tunnel diode created with AMMF (Zr₅₅Cu₃₀Al₁₀Ni₅ composition). Hysteresis on negative sweep due to interface between dielectric and Al electrode (non-AMMF). Asymmetric positive and negative sweeps is due to electrode compositional asymmetry.

FIG. 8: Low voltage (pre-tunneling) IV curve illustrating low conductance (high resistance). The pA level noise of the curve is hypothesized to occur due to probing noise in the measurement system.

FIG. 9: Illustration of the physical layers of a MIMIM HET.

FIG. 10: (a) Logarithmic current versus applied field for MIM diodes with differing dielectric thicknesses. The thickness of the Al₂O₃ dielectrics is listed next to the diode's I-V curve. The diodes all have blanket ZrCuAlNi lower electrodes and 1 mm² shadow masked ZrCuAlNi upper electrodes. (b) Asymmetry metric for each MIM diode calculated at the asymmetry field indicated.

FIG. 11: Cross sectional illustration of a HET structure fabricated with ZrCuAlNi AMMF electrodes.

FIG. 12: (a) Illustration of layer material and thicknesses used in the first MIM with an AMMF electrode. (b) I-V curve of the MIM represented in (a).

FIG. 13: Overlaid I-V curves of MIM diodes with differing tunnel dielectric thicknesses. The thickness of the Al₂O₃ dielectric is listed next to the diode's I-V curve. The diodes all have blanket ZrCuAlNi AMMF lower electrodes and 1 mm2 shadow masked ZrCuAlNi AMMF upper electrodes.

FIG. 14: Electron diffraction image from 10 nm TiAl₃ film that was heated to 300° C. during solution based AlPO dielectric depositions for 1 min per AlPO layer (TEM of stack used for diffraction is next image).

FIG. 15: 200 nm TiAl₃ AMMF RMS roughness is 2 nm.

FIG. 16: 200 nm ZrCuAlNi AMMF RMS roughness run at the same time as FIG. 15 is 0.5 nm. Seeing as TiAl₃ AMMF MIM diodes work well, RMS roughness is not a predictor of alone of MIM diode performance.

FIG. 17: TEM of nanolaminate made with ZrCuAlNi AMMF, TiAl₃ AMMF and AlPO layers. Image illustrates a lack of crystalline features in films. TEM prep layers are on top of top ZrCuAlNi AMMF (C and Ir), SiO₂ is underneath lower ZrCuAlNi AMMF.

FIG. 18: Representative XRD spectrum obtained from a 200 nm ZrCuAlNi AMMF deposited on to glass.

FIG. 19: (a) An electron diffraction pattern from a 200 nm ZrCuAlNi AMMF deposited onto a 1 inch by 1 inch Si═SiO2 substrate. (b) An electron diffraction pattern from the Si substrate.

FIG. 20: TEM micrograph of a ZrCuAlNi AMMF/aluminum phosphate glass nanolaminate.

FIG. 21: Current-Voltage curves from MIM diodes fabricated with either ZrCuAlNi AMMF or TiAl₃ AMMF blanket lower electrodes and evaporated Al upper electrodes. Asymmetry of ZrCuAlNi MIM is 74.2 at 1.8 V, asymmetry of TiAl₃ MIM is 14.3 at 1.8 V. This illustrates a lowering of asymmetry by the use of an AMMF with a lower workfunction (closer to Al work function). The net current of the TiAl₃ MIM diode is lower, which is hypothesized to occur due to the ALD Al₂O₃ nucleating faster on the native oxide of the TiAl₃ giving rise to a net thicker dielectric.

FIG. 22: Current-voltage curves from bottom blanket TiAl₃ diodes with evaporated Al upper electrodes and Al₂O₃ dielectrics.

FIG. 23: I-V curves from a HET fabricated with ZrCuAlNi electrodes and Al₂O₃ dielectrics.

FIG. 24: Graphical representation of the mathematical dispersion equations and resulting dispersion of incident light incident on (a) spherical isotropic materials, (b) elliptical anisotropic materials, and (c) hyperbolic anisotropic materials. Laminate structures shown in (b) and (c) are taken from TEM micrographs of laminate materials.

FIG. 25: Materials analysis data of an anisotropic, dispersion, laminate material fabricated with TiAl₃/Aluminum Phosphate glass (AlPO) bilayers. (a) TEM micrograph of a 10 bilayer TiAl₃/AlPO laminate. (b) Electron diffraction data collected on the laminate structure shown in (b). (c) XPS depth profile data overlaid on a TEM micrograph taken through a laminate fabricated concurrently with the laminate shown in the TEM images.

FIG. 26: Real components of the complex, isotropic amorphous metal and AlPO dielectric responses along with effective, anisotropic dielectric responses of laminate (a) ZrCuAlNi/AlPO and (b) TiAl₃/AlPO structures. Red is the bulk, isotropic dielectric response of the amorphous metal, black is the isotropic AlPO dielectric response, blue is the xy-plane dielectric response (∈_{xy}), and green is the z (propagation direction) dielectric response (c).

FIG. 27: Normalized measured to modeled error versus metal/dielectric ratio of reflectance data collected using T_{M} polarized light with laminates fabricated with bilayers comprised of (a) ZrCuAlNi/AlPO and (b) TiAl₃/AlPO. (c) Standard deviation of normalized measured to modeled error versus metal/dielectric ratio of data shown in (c) from a TiAl₃/AlPO laminate. (d) TEM micrograph of a TiAl₃/AlPO laminate fabricated concurrently with the laminate measured for (b) and (c).

FIG. 28: Normalized error vs. metal/dielectric ratio data illustrating the divergence of model fit (error>0) for two laminates (ZrCuAlNi/AlPO and TiAl₃/AlPO) measured at both 20° and 45°.

FIG. 29: (a) XPS depth profile of neutrally-charged metals from nanolaminated structure with four bilayers of AlPO-topped ZrCuNiAl (b) XPS depth profile of selected ions from the same nanolaminated structure.

FIG. 30: (a) TEM micrograph of Cu—AlPO—ZrCuAlNi laminate with the direction of the XPS profile indicated. (b) XPS depth profile of the structure pictured in (a).

FIG. 31: (a) TEM micrograph of Ti—AlPO—ZrCuAlNi stack with the direction of the accompanying XPS depth profile indicated. (b) XPS depth profile taken along direction indicated in TEM of structure.

FIG. 32: (a) XPS profile of ZrCuNiAl deposited onto high-temperature annealed AlPO at 30 W. (b) XPS profile of ZrCuNiAl deposited onto high-temperature annealed AlPO at 60 W

FIG. 33: (a) Labeled schematic diagram of ZrCuAlNi—AlPO laminate (b) Intensity profile of phosphate, phosphide and aluminum metal from diagrammed laminate rotated such that the intensities are aligned to their corresponding layers in the surrounding images.

FIG. 34: (a) Graph of Zirconium-photoelectron binding energies from laminated structure. (b) Corresponding intensity/depth profile of laminate with various types of zirconium labeled.

FIG. 35: (a) TEM micrograph of ZrCuAlNi—ZircSOx laminated structure with XPS depth-profile overlay showing all oxidized metals present, as well as oxide and sulfide concentrations. (b) Corresponding XPS depth profile of metals from laminate accompanied by O²⁻ to allow for scaling.

FIG. 36: (a) TEM micrograph of ZrCuAlNi-HafSOx laminated structure with XPS depth-profile overlay showing all oxidized metals present, as well as oxide and sulfide concentrations. (b) Corresponding XPS depth profile of metals from laminate accompanied by O²⁻ to allow for scaling.

FIG. 37: (a) XPS depth profile of 100-nm HafSOx film. (b) XPS depth profile of 100-nm ZircSOx film. (c) XPS depth profile of crystalline copper sulfate

FIG. 38: Electron diffraction patterns taken from the top interface (a) and bottom interface (b) of an amorphous metal/oxide nanolaminate metamaterial.

FIG. 39: A TEM micrograph of an amorphous ZrCuAlNi/AlPO metamaterial.

FIG. 40: A TEM micrograph illustrating the selective crystallization of an (as deposited) amorphous ZrCuAlNi/AlPO nanolaminate. Thermal conductivity is hypothesized to be significantly higher parallel to the crystallized metal layers when compared to the thermal conductivity perpendicular to the layers.

### DETAILED DESCRIPTION

Amorphous, multi-component metallic films (AMMFs) are herein disclosed for application, for example, in vertical transport thin-film transistors (VTTFTs), and metal:insulator:metal (MIM) tunnel diodes. Specifically, multi-component combinations of metals of differing atomic radii are selected as appropriate constituents for the realization of high-performance conductors in TFT applications and MIM tunneling diodes. These AMMFs may be compositionally homogeneous or inhomogeneous.

The AMMFs can be utilized as electrodes in two terminal and three terminal electronic devices. In particular, the AMMFs can be utilized as electrodes for metal:insulator:metal tunneling diodes. Additionally, AMMFs can be utilized as electrodes in metal:semiconductor:metal diodes and metal:insulator:metal:insulator:metal hot electron transistor electronic devices.

### Metal Insulator Metal Tunnel Diodes

The MIM tunnel diode involves the incorporation of AMMFs into MIM structures as the metal electrodes. The homogeneously smooth surface of AMMFs offer an advantage over crystalline metals in that there fewer surface imperfections that can cause inhomogeneity in the electric field of the device. Areas of high electric field would cause stress on the insulator resulting in poor diode performance and failure. The measured diode curves exhibit very high pre-turn on resistance and consistent/repeatable exponential increase of tunneling current with increasing voltage. These characteristics support the existence of a high quality interface between the AMMF electrode and the tunneling oxide.

Additionally, the multi-component nature of AMMFs inherently allows for flexibility of stoichiometry. This stoichiometric flexibility in turn allows for the engineering of the work function of AMMFs. Asymmetric electrode work functions allows for the engineering of asymmetric tunneling turn-on voltages and current characteristics in positive and negative operating voltages. This is exhibited in the supplied current-voltage (IV) curves. Examples of fabricated devices disclosed herein (see FIG. 2) have an AMMF (Zr₅₅Cu₃₀Al₁₀Ni₅) as the grounded lower electrode, a 10 nm Al₂O₃ tunneling insulator deposited via atomic layer deposition (ALD), and an Al upper electrode through which the voltage is applied.

In certain embodiments, the MIM diodes exhibit negligible current flow between the electrodes in the off-state, but once the applied voltage reaches the Fowler-Nordheim tunneling effect threshold the current increases exponentially.

### Vertical Transport Thin-Film Transistors

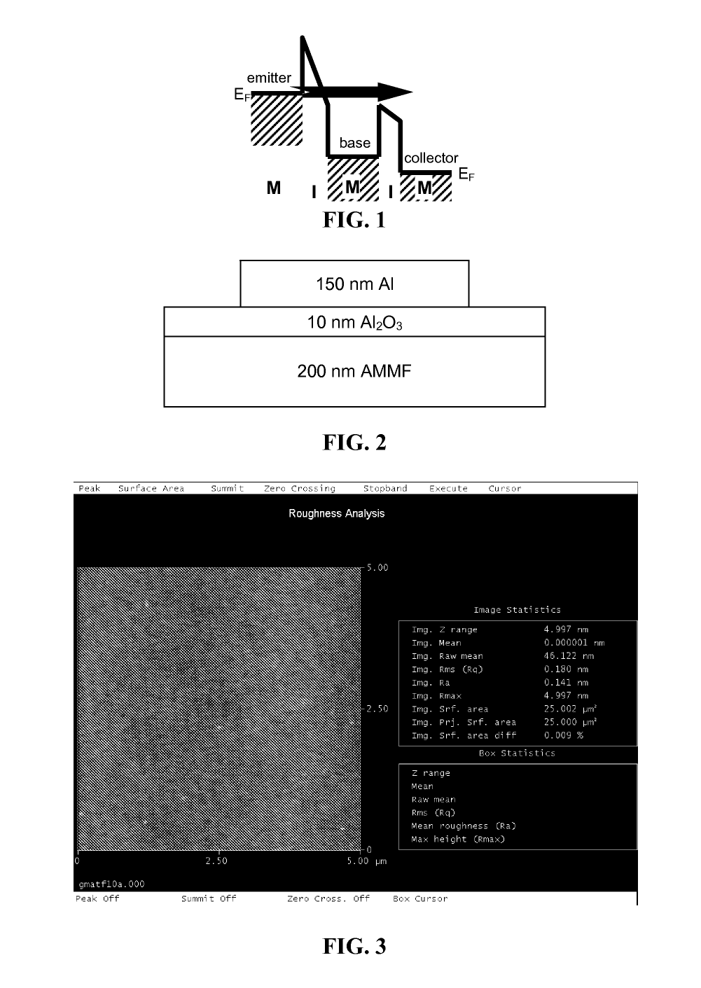

The thin-film transistor (TFT) applications involve the incorporation of thin and ultra-thin AMMFs into vertical transport TFTs (VTTFTs). As evident from its name, VTTFTs employ vertical carrier transport, rather than conventional lateral carrier transport, with the intention of dramatically improving the TFT high frequency performance, since vertical dimensions can more conveniently and economically be controlled during TFT fabrication than lateral dimensions. There are two primary VTTFT types: hot electron transistors (HETs) and permeable base transistors (PBTs). Both HETs and PBTs possess three metal contact layers, usually denoted as the emitter, base, and collector. Energy band diagram representations of a representative MIMIM HET is shown in FIG. 1.

AMMFs offer several advantages for use as emitter and base contacts. For example, AMMFs may be used as the first-deposited, bottom layer in a HET or PBT, which, in conjunction with its insulator or semiconductor overlayer, will function as the emitter which injects carriers (i.e., electrons or holes) into the base. A unique property of certain embodiments of an AMMF thin film is its amorphous nature which enables it to possess homogeneously smooth surface. This physical property allows subsequent insulator, semiconductor, and/or metal layers to be deposited onto the surface of this contact layer to realize a uniform electric potential barrier between layers. The availability of a homogeneously smooth interface between the AMMF emitter contact and the overlying insulator or dielectric will facilitate uniform emitter carrier injection.

An AMMF could also be used as a base contact in an MIMIM HET structure. Surface smoothness and a homogeneous, contiguous layer are factors that AMMFs appears to be uniquely suited to meet. Additionally, in a HET this base layer must be thin enough (˜10-50 nm) so that a significant fraction of the carriers injected from the emitter into the base can transit ballistically or near-ballistically through the base. If the base thickness is not precisely controlled, the performance of the HET will be compromised, as discussed in the following.

An amorphous metal solid is a rigid material whose structure lacks crystalline periodicity; that is, the pattern of constituent atoms or molecules does not repeat periodically in three dimensions. The amorphous metals are multi-component, that is, they comprise at least two or more metal components, in order to frustrate crystallization. Hence, amorphous metals are identified herein with the descriptor amorphous multi-component metallic films (AMMFs). AMMFs are substantially amorphous such that crystalline aspects of the film are suppressed. The suppression of crystalline aspects creates a uniform potential barrier at the interface formed between an AMMF and a dielectric. In one aspect, whether or not a material is amorphous can be measured by testing the resistivity of the material. For example, an amorphous material exhibits resistivity at least an order of magnitude greater than the crystalline metals. In another embodiment, a material is an AMMF if the resistivity is at least 100 μΩ-cm, more particularly at least 150 μΩ-cm, and especially 100-250 μΩ-cm.

In certain examples, the AMMFs may have a homogeneously smooth surface. For instance, the root mean square (RMS) roughness of the AMMF surface may be less than 3 nm, more particularly less than 0.5 nm. In other embodiments, the AMMF surface is characterized by a surface that lacks sharp morphologies characteristic of crystalline metals. The AMMF surface can acts as a potential barrier to nucleation that remains stable below 500° C.

In one embodiment, the AMMF films are thin (less than 200 nm) or ultra thin (less than 20 nm), smooth (less than 2 nm RMS roughness), conducting (less than 500 μΩ-cm), and/or mechanically robust.

The AMMF can be made from at least one element selected from Groups II-XV. According to particular embodiments, the element(s) is selected from Groups IV, V, VI, X, Al, Mg, Sn or Zn. Illustrative AMMFs include ZrCuAlNi and TiAl₃. In certain embodiments, the multi-component combinations of the metallic elements with varying atomic radii are selected to result in a deep eutectic point for emitter and base conductors in the realization of high-performance VTTFTs or MIM diodes.

The AMMFs may be formed by any film-forming technique such as sputtering, solution deposition, or electron-beamed deposition. For example, multi-source RF (or DC) magnetron sputtering using elemental or mixed composition metal targets of Zr, Cu, Ni, and Al may be employed to make the AMMFs. Sputter deposition affords AMMFs a distinct manufacturing advantage over similarly smooth semiconductors deposited using advanced epitaxial technologies such as molecular beam epitaxy (MBE) or metal-organic chemical vapor deposition (MOCVD). In certain embodiments, the MIM diodes can be made with simple, low cost fabrication techniques (for example, sputtering for the AMMF lower electrode, ALD for the insulator layer, and shadow masking for the upper electrode). In certain embodiments, the AMMFs are not etched. The ability to deposit thin/smooth AMMFs at room temperature via sputtering that stay amorphous (and smooth) with heated processing lends itself to applications in VTT and MIM tunnel diode applications.

The AMMF may be deposited on any type of substrate (e.g. silicon, glass, or a polymeric material such as thermoplastic or thermoset).

The dielectric layer for use in association with the AMMF may be made from any type of dielectric material. Illustrative materials include Al₂O₃, aluminum phosphate, silicon dioxide, a metal halide (e.g., calcium fluoride), zirconium oxide, hafnium dioxide, titanium dioxide, SnO₂, ZnO and combinations thereof.

The dielectric layer may be made by any layer-forming process such as, for example, sputtering, atomic layer deposition (ALD), solution processing, chemical vapor deposition (CVD) or plasma enhanced chemical vapor deposition (PECVD). In the case of ALD, it is possible to form an insulator layer with 12 to 500 pulses, more particularly 12 to 225 pulses. In certain embodiments, the insulator layer may be made with as few as 5 pulses. The electronic structure (e.g., MIM diode) may include more than one insulator layers between conductive layers (e.g, the lower and upper electrodes of a MIM diode).

As described above, other conductive layers (e.g, an electrode) may be included in the structures that also include at least one AMMF. Such conductive layers may be made from any conductive material such as for example, a metal (Ru, Ir, Pt, Al, Au, Ag, Nb, Mo, W, Ti), or a metal nitride (TiN, TaN, WN, NbN). Such conductive layers may also be made by any layer-forming process such as, for example, sputtering, atomic layer deposition, solution processing or electron-beam deposition.

### EXAMPLES

The material and electrical characterization of AMMFs and the electrical characterization of electronic devices fabricated with AMMF electrodes are described below in the examples. The following data illustrates:
1) The fact that AMMFs with homogeneously smooth surfaces can be deposited via sputtering
2) The fact that such films maintain their surface homogeneity after certain types of post-deposition thermal processing.
3) The substantially amorphous nature of such films.

### Materials Analysis

Materials analysis was performed to provide an understanding of the growth rates, composition, atomic order, surface morphology, and work function characteristics of ZrCuAlNi AMMFs. An understanding of an AMMF's material characteristics was leveraged in the creation of a process through which electronic devices with ZrCuAlNi AMMF electrodes are fabricated. All AMMFs analyzed were deposited onto 1 inch by 1 inch substrates consisting of Si with 100 nm of thermally grown SiO₂ unless noted otherwise.

### ZrCuAlNi AMMF Growth Characterization

Sputter deposition parameters were varied to investigate the impact of pressure, power, and voltage on the deposition rate of AMMFs. The ZrCuAlNi AMMFs used to investigate AMMF deposition parameters were grown using a three inch vacuum arc melted metallic target manufactured by Kamis, Inc. To create a step in the deposited ZrCuAlNi AMMF, Kapton tape is applied to the edge of the substrate prior to the sputter deposition. After the deposition, the tape is removed and the step is measured with a KLA/Tencor Alpha Step 500 profilometer. The Alpha Step 500 used to measure the film thickness has good precision down to 60 nm. At film thicknesses below 60 nm, the Alpha Step 500 does not give repeatable measurements, hence AMMF depositions for growth rate characterizations are targeted at thicknesses greater than 60 nm but are not limited to thicknesses greater than 60 nm.

Deposition times between 10 minutes and 25 minutes yield growth rates that average 23 nm/min with a standard deviation of 2 nm/min. The ZrCuAlNi target used to grow the AMMFs is conducting, therefore RF magnetron sputtering is not needed. DC magnetron sputtering offers faster deposition rates, which allows for the use of lower applied power. A low applied deposition power also may be useful in creating a pristine interface between the deposited AMMF and the substrate that the AMMF is being deposited onto. A survey of DC magnetron powers shows a consistent growth rate near 10 nm/min is achieved by the application of 60 W at a pressure of 3 mtorr. A 10 nm/min deposition rate allows for quick calculations of the deposition time required for targeted AMMF thickness. Therefore, a power of 60 W at a pressure of 3 mtorr is employed as the standard condition for ZrCuAlNi AMMF depositions. 60 W of DC power at a pressure of 3 mtorr using a 20 sccm flow of Ar is referred to as the standard deposition conditions.

Investigations into AMMF Composition

The composition of ZrCuAlNi AMMFs deposited at three sputtering conditions was analyzed via electron probe micro-analysis (EPMA) to determine if composition changed with differing sputter conditions. Table lists the investigated sputter deposition conditions and the associated weight and atomic percentages of the constituent elements in the AMMF. It is seen that over a wide range of deposition conditions, the composition of the ZrCuAlNi AMMF does not significantly change from a composition near Zr₄₀Cu₃₅Al₁₅Ni₁₀. The ZrCuAlNi AMMF was deposited with the standard deposition conditions. During the XPS analysis, the substrate is positioned at a grazing angle relative to the x-ray source to improve the depth resolution of the profile. An Ar ion beam is used to sputter the AMMF film in order to obtain a depth profile. The XPS depth profile data is in good agreement with the EPMA atomic concentration data, showing a composition near Zr₄₀Cu₃₅Al₁₅Ni₁₀. The decrease in Zr(0) seen at the surface of the film is due to native oxidation, which forms a Zr(IV) oxide.

TABLE 1
Elemental composition of ZrCuAlNi AMMFs grown at different sputter
conditions as obtained via EPMA. The first number is the atomic
concentration while the second number is the atomic percent.

| Deposition | | | | | |
|---|---|---|---|---|---|
| Conditions | Zr | Cu | Al | Ni | O |
| 3 mtorr, 150 W RF, | 51.2/37.4 | 33.4/35.0 | 5.7/14.0 | 8.9/10.0 | 0.9/3.6 |
| 20 sccm Ar | | | | | |
| 5 mtorr, 75 W DC, | 51.0/36.9 | 34.0/35.2 | 5.8/14.1 | 8.1/9.1 | 1.2/4.8 |
| 20 sccm Ar | | | | | |
| 2 mtorr, 175 W RF, | 50.7/36.9 | 33.3/34.8 | 5.6/13.8 | 9.6/10.9 | 0.9/3.5 |
| 20 sccm Ar | | | | | |

### ZrCuAlNi AMMF Atomic Order and Surface Morphology

The amorphous nature of AMMFs is considered an important characteristic allowing for the realization of a homogeneously smooth AMMF surface. To illustrate the level of atomic order present in the studied ZrCuAlNi AMMFs, both x-ray diffraction (XRD) analysis and electron diffraction analysis is presented.

FIG. 18 presents an XRD spectrum taken from a 200 nm ZrCuAlNi AMMF that was deposited with the standard conditions onto a glass substrate to avoid crystalline XRD signals from the substrate. The spectrum presented has the glass substrate XRD spectrum subtracted to show only the spectrum from the AMMF. The y axis of the presented data is formatted with a logarithmic y axis to illustrate the lack of crystalline peaks in the spectrum. The XRD spectrum indicates the ZrCuAlNi AMMF is amorphous.

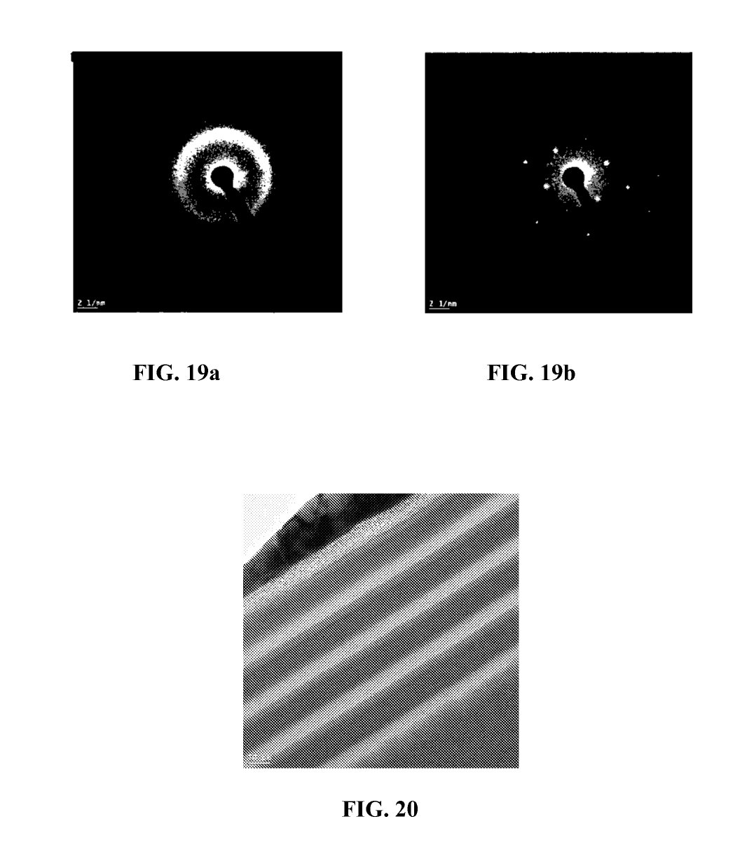

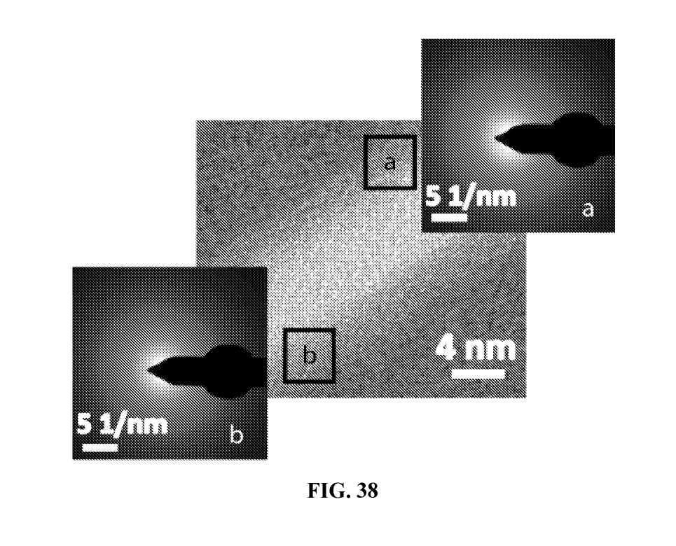

FIG. 19(a) presents an electron diffraction pattern from a 200 nm ZrCuAlNi AMMF deposited with the standard conditions. The absence of discrete points in the electron diffraction pattern indicates that the film has no long-range order. The presence of a single, diffuse ring in the electron diffraction pattern suggests that the film is substantially amorphous. An electron diffraction pattern obtained from the Si substrate is shown in FIG. 19(b). The Si electron diffraction pattern presents an electron diffraction pattern of a single crystalline material in order to highlight the differences seen in electron diffraction patterns between single crystalline and amorphous materials. Electron diffraction analysis also verifies the amorphous nature of the amorphous metal/oxide nanolaminate metamaterials. FIG. 38 shows two electron diffraction patterns taken from the top (a) and bottom (b) interfaces in a metamaterial fabricated with bilayers comprised of Zr₄₀Cu₃₅Al₁₅Ni₁₀ and aluminum oxide phosphate (AlPO). The AlPO was deposited via solution deposition. Precursor solutions were prepared by dissolving Al(OH)₃ in 2 mole equivalents of HNO₃ (aq) and the appropriate amount of H₃PO₄ (aq). Al(OH)₃ dissolution was accomplished by stirring under moderate heat (80-90° C.) in a water bath for 24 h. Total metal ion concentration was 0.1 M, with an aluminum to phosphate ratio of 5:3. 18 M de-ionized water was used for the preparation of all solutions. The solution was spin-coated onto the amorphous multi-component metal films at a speed of 3000 RPM for a 30 s duration, followed by a treatment at 300° C. for 1 min on a hotplate under ambient atmospheric conditions. The samples were prepared on 1″×1″ substrates comprised of 100 nm of thermal SiO₂ on Si. The atomically smooth, repeatable interfaces enable low levels of optical scattering due to defects or roughness. Low levels of interfacial scattering decrease the loss associated with off angle reflections which, in turn, maximizes the transmission of light through the metamaterial.

X-ray diffraction (XRD) analysis was carried out to verify the amorphous nature of the AMMFs deposited via RF magnetron sputtering. FIG. 5 shows XRD spectra of films as-deposited and after a 300° C. anneal in air for 1 hour. The broad peak at 2θ˜38° is indicative of the short range order that exists in an amorphous film. Any crystalline film would manifest itself in the XRD analysis as sharp peaks. The resulting 2θ position of these peaks would depend on the specific crystalline phases associated with the combinations of the constituent elements in the film that had crystallized.

TABLE 2
RMS surface roughness of ZrCuAlNi AMMFs grown at different sputter
conditions as analyzed via atomic force microscopy (AFM). All films
were deposited using a 20 sccm flow-rate of Ar.

| Pressure | | Thickness | RMS roughness |
|---|---|---|---|
| (mTorr) | Power (W) | (nm) | (nm) |
| 3 | 150 (RF) | 253 | 0.11 |
| 3 | 150 (RF) | 252 | 0.13 |
| 5 | 150 (RF) | 188 | 0.17 |
| 3 | 100 (RF) | 122 | 0.21 |
| 3 | 150 (RF) | 505 | 0.22 |
| 5 | 100 (RF) | 38 | 0.20 |
| 5 | 100 (RF) | 30 | 0.18 |
| 3 | 60 (DC) | 38 | 0.20 |

ZrCuAlNi AMMFs deposited with several sputter conditions were analyzed via atomic force microscopy (AFM) to evaluate the surface morphology of the AMMFs. Table 2 lists the root mean square (RMS) roughness of the films as well as the sputter conditions used for the depositions of the ZrCuAlNi AMMFs. The data indicates that the average RMS roughness of the AMMFs is 0.17 nm, with a RMS roughness sample standard deviation of 0.04 nm.

AFM data was collected on ZrCuAlNi AMMF samples annealed in air to determine the impact of temperature on surface roughness. The data, presented in Table 3, shows that the AMMF surface morphology remains homogeneously smooth (RMS roughness less than 0.2 nm) with anneal temperatures in air below 350° C. As the temperature is increased above 400° C., the AMMF surface changes color. A change in surface color is indicative of the growth of a surface oxide. XPS depth profile data collected on as deposited ZrCuAlNi AMMFs shows that the AMMF surface is covered with a native Zr(IV) oxide. XRD spectra collected from as deposited ZrCuAlNi, however, show no sign of a ZrO₂ peak. The lack of peaks indicates either the native surface Zr(IV) oxide is amorphous, or the native Zr(IV) oxide is too thin to be seen in the spectrum. The RMS roughness measured on ZrCuAlNi AMMFs annealed at 550° C. provides insight into the affect of film thickness on surface roughness. The 76 nm ZrCuAlNi AMMF film annealed at 550° C. has an RMS roughness of 13.3 nm, while the 505 nm ZrCuAlNi AMMF film annealed at 550° C. has a surface roughness of 110 nm.

TABLE 3
RMS surface roughness of ZrCuAlNi AMMFs annealed in air at different
temperatures as analyzed via atomic force microscopy (AFM).

| Temperature | Thickness | |
|---|---|---|
| (° C.) | (nm) | RMS roughness (nm) |
| 300 | 253 | 0.11 |
| 300 | 188 | 0.10 |
| 325 | 38 | 0.17 |
| 325 | 30 | 0.17 |
| 350 | 38 | 0.18 |
| 350 | 30 | 0.18 |
| 400 | 253 | 1.9 |
| 400 | 505 | 1.7 |
| 550 | 505 | 110 |
| 550 | 76 | 13.3 |

XRD spectra of ZrCuAlNi AMMFs annealed at temperatures greater than 350° C. show spectral peaks at 2θ values of approximately 30°, 34°, 50°, and 58°. These four spectral peaks are indicative of the presence of tetragonal ZrO₂.

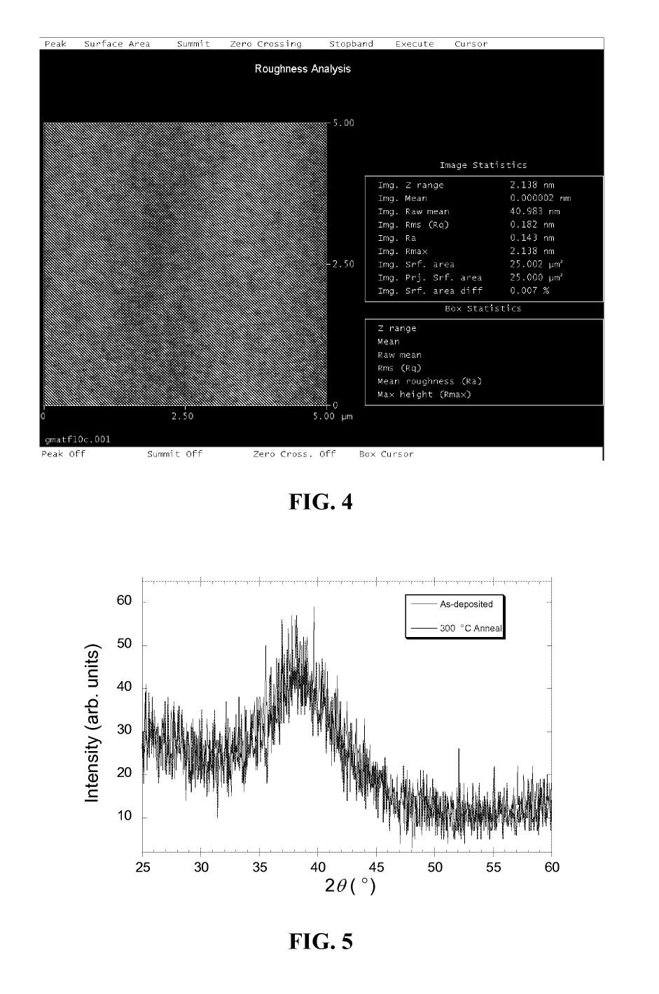

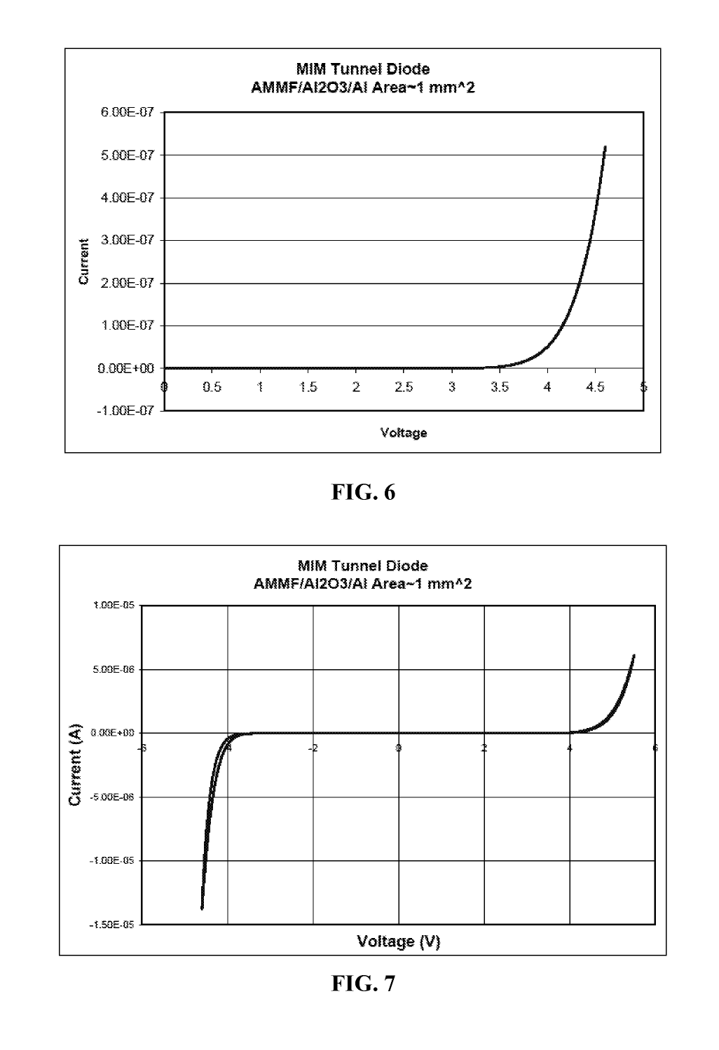

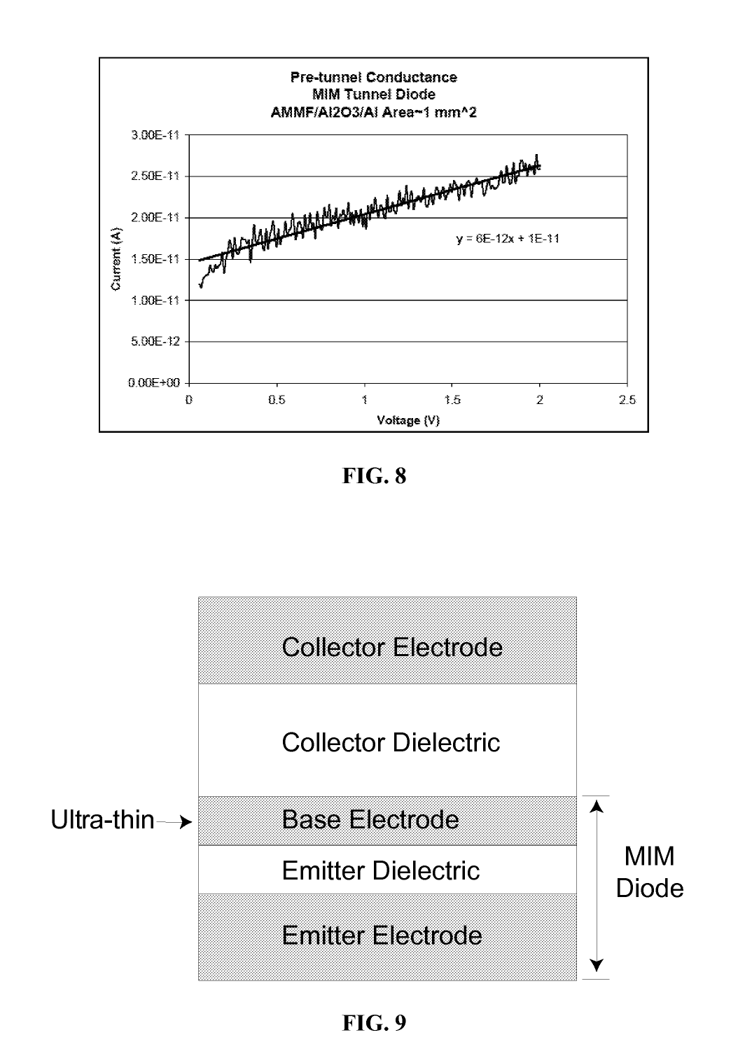

The atomic force microscope (AFM) image in FIG. 3 indicates that an ultra-thin AMMF (less than 50 nm based on profilometer measurements and growth rate characterization) can be deposited via RF sputtering of a multicomponent target onto a Si<100> substrate at room temperature (no substrate heating). Furthermore, it has been discovered that certain AMMFs retain their surface smoothness even after certain types of thermal processing. The AFM image in FIG. 4 shows that the same film (less than 50 nm) annealed in air at 350° C. does not roughen. The amorphous metallic oxide layers have been deposited via solution deposition at temperatures below 350° C. in air, and therefore do not roughen the amorphous metal layers.

### ZrCuAlNi AMMF Resistivity Characterization

The resistivity of ZrCuAlNi AMMFs with varying thicknesses, deposited under differing sputter conditions, was measured using a four-point probe. Resistivity measurements across 17 AMMFs with thicknesses between 30 nm and 605 nm have an average resistivity of 208 μΩ-cm, with a sample standard deviation of 15 μΩ-cm. The coefficient of variation (CV) of a measurement is defined as the sample standard deviation divided by the mean of the sample measurements. In general, a CV of less than 10% suggests a repeatable fabrication process and measurement technique. The CV of the measured ZrCuAlNi resistivity is 7.2% of the average resistivity of the measured films, indicating that the resistivity is repeatable across sputter deposition parameters and film thicknesses. Additionally, the low CV value indicates that the four-point probe resistivity measurement used to collect the sample data is repeatable.

### ZrCuAlNi AMMF Work Function Characterization

The workfunction of electrode materials in two-terminal and three-terminal tunneling devices has a direct impact on the device current-voltage characteristics.

Table 4 presents mean workfunction and workfunction sample standard deviation data measured via Kelvin probe on four materials to allow for comparisons between the ZrCuAlNi AMMF and other materials. The measured workfunction data indicates that the variation of measured ZrCuAlNi AMMF workfunction is on the same order as materials deposited by solution deposition, RF magnetron sputter deposition, and thermal evaporation. Low workfunction variation across a substrate is important to minimize the variation of electronic device performance when the device performance is dependent on electrode workfunction.

TABLE 4
Workfunction data collected from four different metal films.

| | Deposition | Mean Workfunction | Sample Standard |
|---|---|---|---|
| Film Type | Technique | (eV) | Deviation (eV) |
| Al | thermal evaporation | 3.957 | 0.015 |
| MoW | RF Magnetron | 4.777 | 0.009 |
| | Sputtering | | |
| ZrCuAlNi | DC Magnetron | 4.705 | 0.033 |
| AMMF | Sputtering | | |
| Ag | Solution Deposition | 5.153 | 0.023 |

### Homogeneously Smooth, Ultra-Thin ZrCuAlNi AMMFs

The base electrode of a HET must be ultra-thin to ensure a low scattering rate of the electrons that comprise the device current between the emitter and collector electrodes. Additionally, the interfaces between the base electrode of a HET and the dielectrics on either side of the base layer (i.e., the collector and emitter dielectrics) should be homogeneously smooth. A homogeneously smooth interface between an electrode and a tunneling dielectric in a MIM diode may be important for MIM diode operation. In the cases of the base electrode of a HET and the electrode of a MIM diode, a homogeneously smooth interface allows for a uniform electric field between an electrode and adjacent dielectrics. As uniform electric fields are required for repeatable HET and MIM tunnel diode operation, the AMMF can be used for the emitter, base, or collector electrode material of a HET or a MIM diode.

FIG. 20 presents a transmission electron microscope (TEM) micrograph of a ZrCuAlNi AMMF/aluminum phosphate glass (AlPO—light grey) nanolaminate with 20 nm targeted bilayer thicknesses. The 10 nm ZrCuAlNi AMMF layers are seen to be contiguous with homogeneously smooth interfaces through the analysis area. Note that the interface between the base 200 nm ZrCuAlNi AMMF (dark) layer and the first AlPO (dark grey) layer is rough. The contiguous nature of the ultra-thin AMMF layer and homogeneously smooth interfaces between the ZrCuAlNi AMMFs and neighboring dielectrics in FIG. 20 indicate that AMMFs may be used for the base electrode material of HETs as well as the electrode material of MIM diodes and HETs.

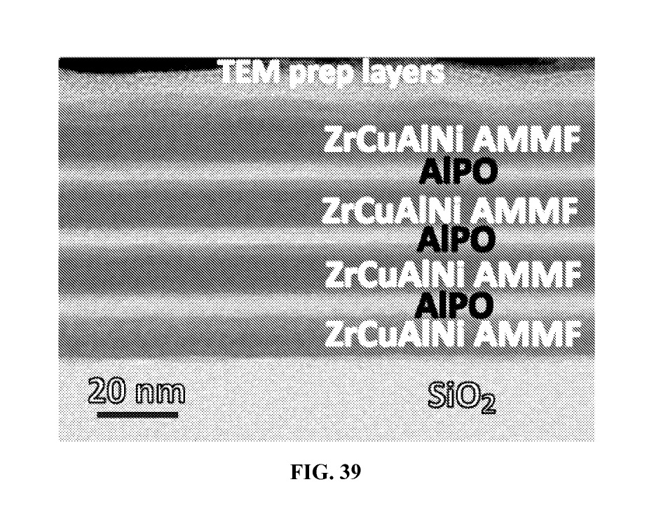

The ability to reproducibly fabricate atomically smooth, ultra-thin bilayers of ZrCuAlNi and AlPO employing DC magnetron sputtering (ZrCuAlNi) and solution deposition (AlPO) is also revealed in FIG. 39. The nano-control of the interdiffusion region thickness and stoichiometry with simple deposition techniques illustrates the high level of manufacturability that is realized with the proposed metamaterial fabrication techniques.

### Two-Terminal Device Electrical Characterization

The devices described below are patterned devices fabricated with a ZrCuAlNi AMMF, or are patterned devices with at least one electrode made of a ZrCuAlNi AMMF.

MIM Tunnel Diodes with AMMF Electrodes

The operation of a MIM tunnel diode fabricated with an AMMF electrode may benefit from the homogeneously smooth AMMF surface. A homogeneously smooth AMMF surface creates a uniform interface between a tunneling dielectric and an AMMF electrode. The uniform interface allows for a uniform electric field across the tunnel dielectric, which in turn gives rise to repeatable device operation. The following characterization of MIM tunnel diodes shows current characteristics, zero-bias resistance (ZBR), and I-V asymmetry are modulated through the choice of electrode and tunnel dielectric materials. The thickness of the tunnel dielectric impacts ZBR.

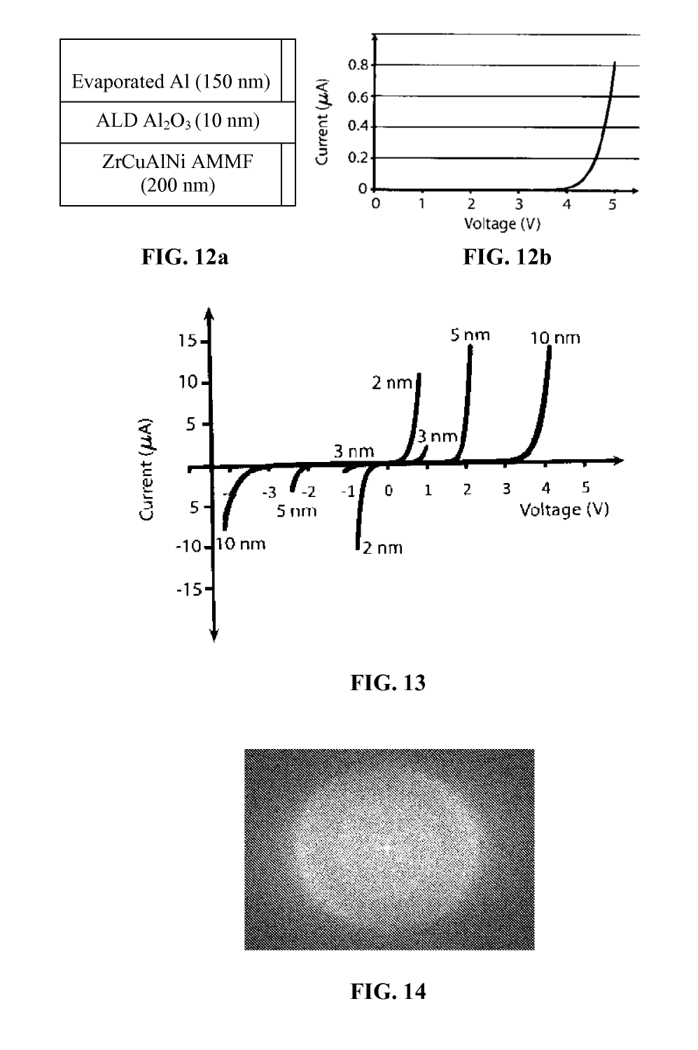

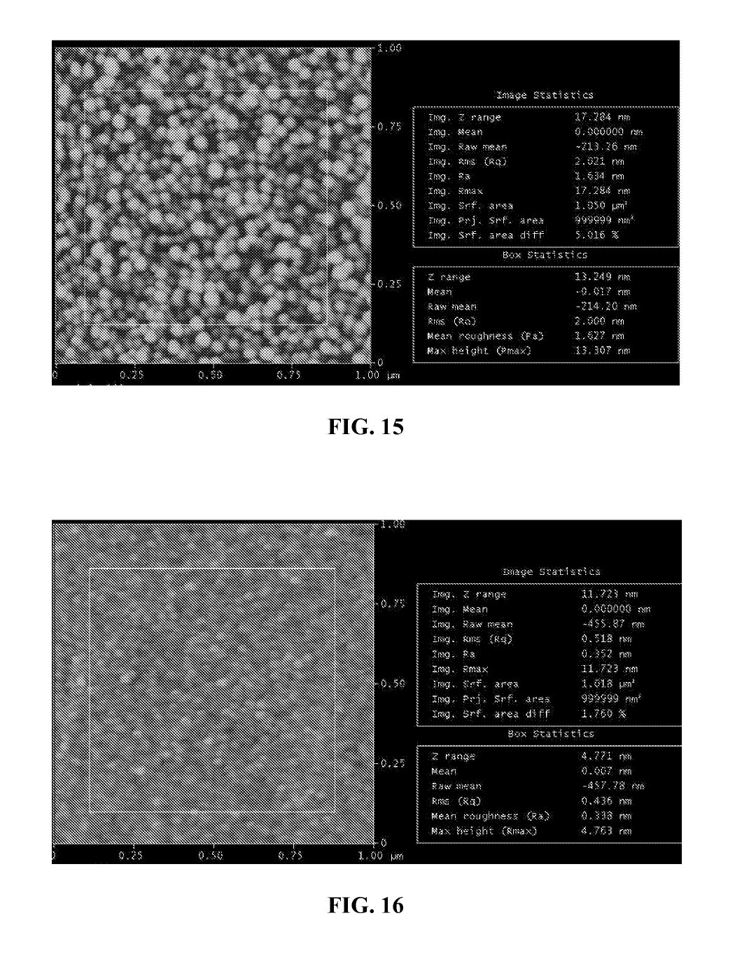

FIG. 12 (a) specifies the layers used for the first MIM diode fabricated with an AMMF bottom electrode. The MIM structures reported herein are fabricated on one inch by one inch Si substrates with 100 nm of thermal SiO₂. The unpatterned ZrCuAlNi bottom electrodes are deposited via DC magnetron sputtering under standard conditions. The Al₂O₃ tunneling dielectric is deposited via ALD. The top Al electrode has and area of ˜1 mm² and is thermally evaporated and patterned via shadowmasking. FIG. 12 (b) presents the I-V curve measured on the first MIM diode fabricated with a ZrCuAlNi AMMF bottom electrode. The I-V curve shows a sharp increase of current as voltage is increased, which is the expected diode behavior.

A series of MIM diodes with differing Al₂O₃ tunnel dielectric thicknesses and symmetric AMMF electrodes were fabricated to investigate the impact that tunnel dielectric thicknesses has on MIM diode I-V curves. The MIM diodes were fabricated with blanket ZrCuAlNi bottom electrodes and ˜1 mm² shadowmasked ZrCuAlNi upper electrodes. FIG. 13 shows an overlay of the I-V curves of MIM diodes with Al₂O₃ tunnel dielectrics of 2, 3, 5, and 10 nm. As expected, there is an inverse correlation between current and tunnel dielectric thickness at a given voltage. An inverse correlation between current and tunnel dielectric thickness is consistent with the Fowler-Nordheim equation.

### I-V Symmetry Modulation of MIM Diodes

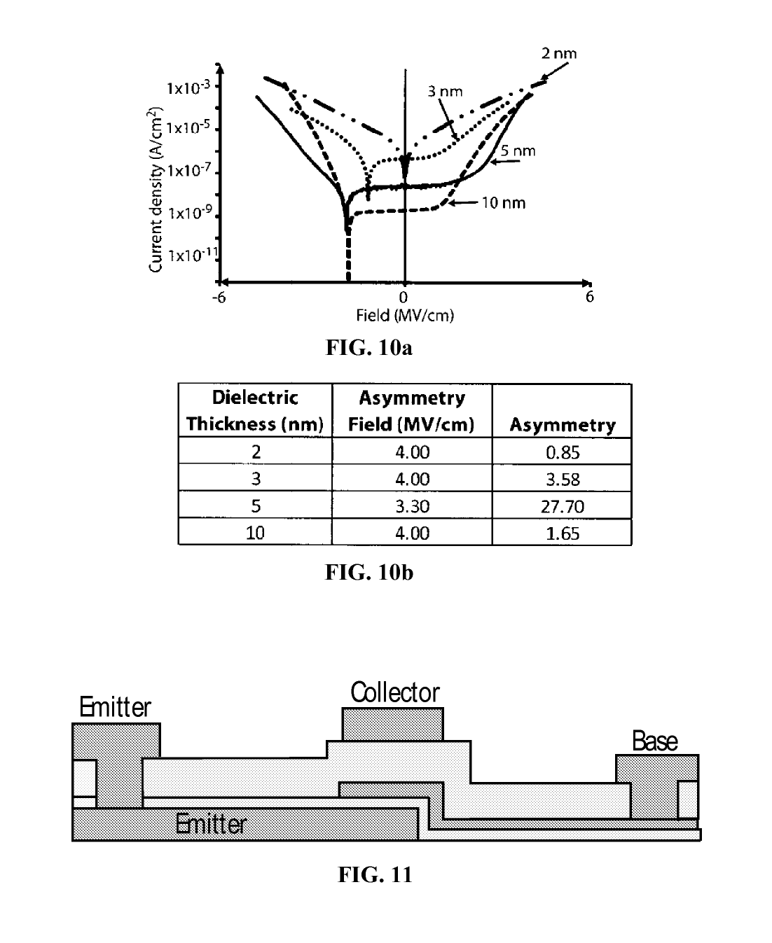

Rectification of an AC signal is one possible application of a MIM diode. To exhibit rectifying behavior without application of a DC voltage offset, a MIM diode must possess asymmetry in its I-V characteristics. FIG. 10 (a) shows evidence of asymmetric interfaces in MIM diodes with two ZrCuAlNi electrodes. The polarity dependence of the current with respect to applied bias in the diodes with dielectric thicknesses greater than or equal to 3 nm provides evidence of asymmetric interfaces. FIG. 10 (b) presents the calculated asymmetry metric as a function of the dielectric thickness of diodes shown in FIG. 10(a). The MIM diodes with thicker tunnel dielectrics are more asymmetric than the MIM diode with a 2 nm dielectric. However, the experimental data of FIG. 10(b) does not reveal a monotonic increase in asymmetry with dielectric thickness. The asymmetry presented in FIG. 10 (a) is observed in MIM diodes with two ZrCuAlNi AMMF electrodes. Therefore, the two potential barriers between MIM diode electrodes and the tunneling dielectric of diodes fabricated with two ZrCuAlNi AMMF electrodes appear to be different. The potential barrier difference is due to the deposition conditions experienced by each interface. The lower interface is formed when Al₂O₃ is deposited via ALD onto a blanket ZrCuAlNi AMMF. An ALD Al₂O₃ deposition imparts little interfacial damage to the lower ZrCuAlNi electrode. There is, however, a native Zr(IV) oxide on the ZrCuAlNi AMMF electrode surface. The upper interface is formed when a shadowmasked ZrCuAlNi AMMF electrode is deposited via DC magnetron sputtering onto an Al₂O₃ tunnel dielectric.

The potential barrier difference is due to the deposition conditions experienced by each interface. The lower interface is formed when Al₂O₃ is deposited via ALD onto a blanket ZrCuAlNi AMMF. An ALD Al₂O₃ deposition imparts little interfacial damage to the lower ZrCuAlNi electrode. There is, however, a native Zr(IV) oxide on the ZrCuAlNi AMMF electrode surface. The upper interface is formed when a shadowmasked ZrCuAlNi AMMF electrode is deposited via DC magnetron sputtering onto an Al₂O₃ tunnel dielectric. The top, shadowmasked electrode is deposited under vacuum, so there is hypothesized to be less Zr(IV) native oxide between the ZrCuAlNi electrode interface and the Al₂O₃ tunnel dielectric. DC magnetron sputtering deposition imparts energy into the Al₂O₃ tunnel dielectric and, therefore, causes some level of deposition-induced damage which is likely to give rise to the observed potential barrier difference. The process-induced asymmetry is not precisely controlled, which creates the deviation in asymmetry trends associated with dielectric thicknesses.

### MIM Diode Zero-Bias Resistance

The zero-bias resistance (ZBR) of a MIM diode is defined as the ohmic resistance seen at very low voltages. Dielectric thickness has the largest effect on ZBR. Without a sufficiently thin dielectric (less than 3 nm of Al₂O₃), the ZBR is greater than 1×10⁹Ω for symmetric MIM diodes. As expected, the ZBR decreases as the thickness of the tunnel dielectric decreases. ZBR begins to drop precipitously when the insulator thickness is reduced to less than about 3 nm. MIM diodes with a 60 nm zinc-tin-oxide (ZTO) tunneling barrier were fabricated to investigate the impact of tunnel barrier height on ZBR. A thickness of 60 nm is large enough to negate the impact that image force lowering caused by the dielectric constant of the tunnel barrier insulator. Symmetric MIM diodes with ZrCuAlNi AMMF electrodes and asymmetric MIM diodes with a blanket bottom ZrCuAlNi electrode and a 1 mm² shadow masked Al upper electrode both showed I-V curves with non-linear, diode behavior. The ZBR of a ZTO MIM diode is measured to be 1:3×10⁴Ω, which is a significantly lower ZBR than MIM diodes fabricated with Al₂O₃ dielectrics.

### Three-Terminal Device Electrical Characterization

A MIMIM HET employs a MIM diode as a hot-electron injector (see FIG. 9). The homogeneously smooth surface of an AMMF is shown to produce reliable MIM diode operation when the electrodes are fabricated with ZrCuAlNi AMMFs. The base electrode of a MIMIM HET must be ultra-thin in order to reduce the probability of hot-electron scattering in the base layer. The TEM micrograph presented in FIG. 20 shows contiguous, ultra-thin AMMF layers having smooth interfaces on either side of the AMMFs. Reliable MIM diode operation and ultra-thin, contiguous films make AMMFs attractive electrode materials for the emitter and base electrodes in a MIMIM HET.

A four-layer mask was employed to fabricate HETs with ZrCuAlNi AMMF electrodes and Al₂O₃ dielectrics (see FIG. 11). The thickness of the emitter and collector Al₂O₃ dielectrics were modulated to investigate the impact of dielectric thickness on HET operation. All of the processing runs employ 200 nm ZrCuAlNi AMMF emitter and collector thicknesses and a 10 nm ZrCuAlNi AMMF base electrode thickness.

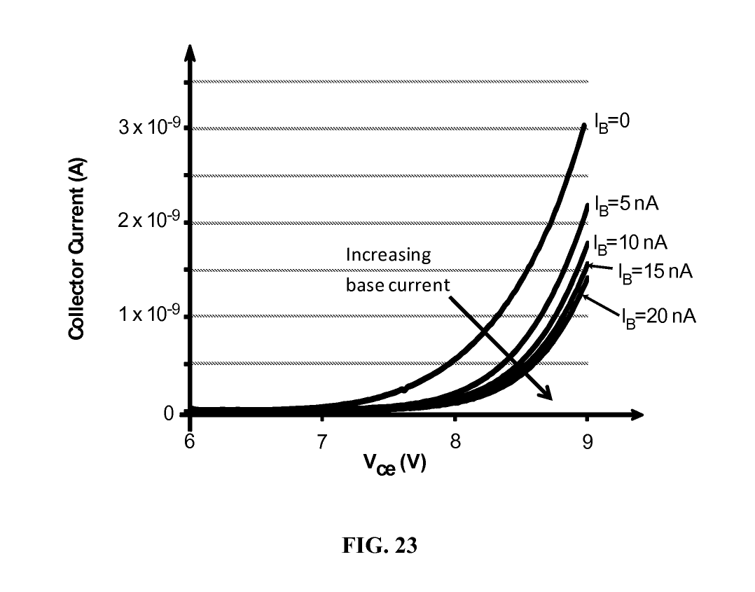

The process used to test HETs fabricated with AMMF electrodes beings with a resistance measurement between the electrodes to check for shorting. The percentage of HETs not exhibiting collector/emitter shorting was approximately five percent. In cases where collector/emitter shorting is not detected, HETs are tested using a common-emitter configuration. FIG. 23 presents a series of common emitter I-V curves with increasing applied base current, collected for a HET fabricated with ZrCuAlNi AMMF electrodes and Al₂O₃ dielectrics. The HET was fabricated with 200 nm thick ZrCuAlNi AMMF emitter and collector electrodes, a 10 nm thick ZrCuAlNi AMMF base electrode, a 5 nm Al₂O₃ emitter dielectric, and a 40 nm Al₂O₃ collector dielectric.

### TiAl₃ AMMFs

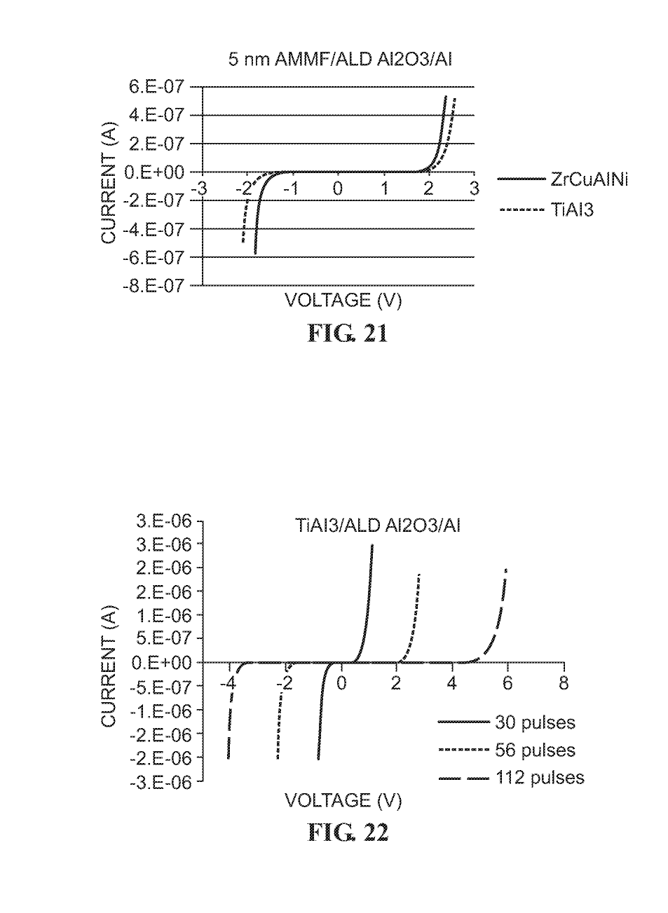

MIM diodes were fabricated with TiAl₃ AMMF blanket lower electrodes with evaporated Al upper electrodes and Al₂O₃ dielectrics. The MIM diode's electronic characteristics are shown in FIGS. 21 and 22. A TiAl₃ AMMF electrode can provide MIM diode and HET fabrication processes that are able to utilize photolithographic patterning. Photolithographic patterning of AMMF electrodes can lead to smaller dimensions and better alignment which, in turn, will lead to more reliable, faster device operations.

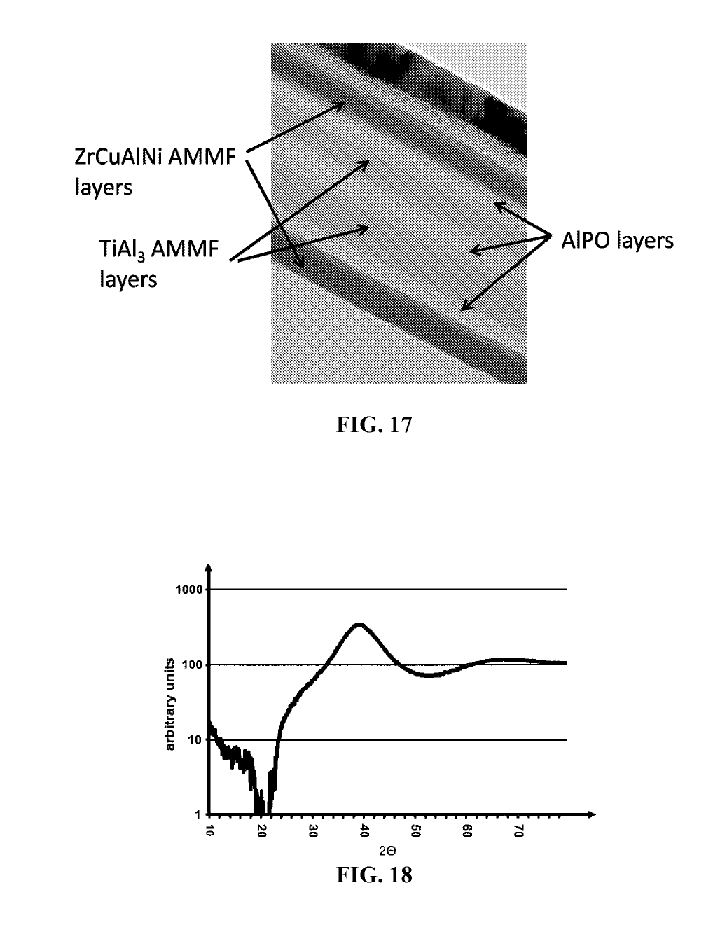

In addition TiAl₃ AMMFs and nanolaminates were fabricated and characterized as shown in FIGS. 14 and 17.

In general, the TiAl₃ AMMFs were made with DC magnetron sputtering using 20 to 200 W, Ar carrier gas and 1 to 20 mTorr.

### Optical Properties

To describe the advances in optical dispersion engineering the differences between isotropic and anisotropic dispersion are described in terms of non-magnetic materials (μ=1). Additionally, the materials described are planar in nature and are represented by an abrupt change in index of refraction in the z direction as light passes into the plane of the material. The dielectric response, ∈, of an isotropic material does not exhibit directional dependance, and is described as

$${k}_{x}^{2} + {k}_{z}^{2} = {n}^{2} \frac{{ω}^{2}}{{c}^{2}} = ɛ \frac{{ω}^{2}}{{c}^{2}} , \qquad ( 1 )$$

where kₓ is the light's momentum component in the plane of the material, k_{z} is the momentum component orthogonal to the material interfaces, n is the material's index of refraction, ω is the angular frequency of the light, and c is the speed of light in a vacuum. The engineered dispersion of incident light is accomplished solely through the modulation of ∈, which is a complex number varying with the frequency of incident light. As light encounters a change in ∈ as it passes from free space (∈=1) to a material with ∈≠1, the direction of the light's momentum (K) changes due to a magnitude change in the z component of the light's momentum (k_{z}). The Poynting vector (S) represents the direction of energy flux, and is coincident with K in an isotropic dielectric material. FIG. 24(a) illustrates the response of light as it passes into an isotropic dielectric material from air.

The dielectric response of layered, anisotropic, dielectric materials has two components, ∈_{xy} in the plane of the material interfaces and ∈_{z} orthogonal to the plane of the material interfaces. Anisotropic dispersion is exhibited only with T_{M} polarized light. T_{M} polarization stipulates that the magnetic field vector is parallel to the material plane as shown in 24(b) and 24(c). Two dielectric response components lead to a dispersion equation

$$\frac{{k}_{x}^{2}}{{ɛ}_{z}} + \frac{{k}_{z}^{2}}{{ɛ}_{xy}} = \frac{{ω}^{2}}{{c}^{2}} , \qquad ( 2 )$$

where ∈_{z} is the dielectric response orthogonal to the material plane and ∈_{xy} is the dielectric response in the material plane. A condition of anisotropic dispersion is that ∈_{z}≠∈_{xy}. Isotropic and anisotropic materials may possess dielectric responses of positive or negative polarity. A negative dielectric response is typically indicative of a metallic material in which electromagnetic waves decay.

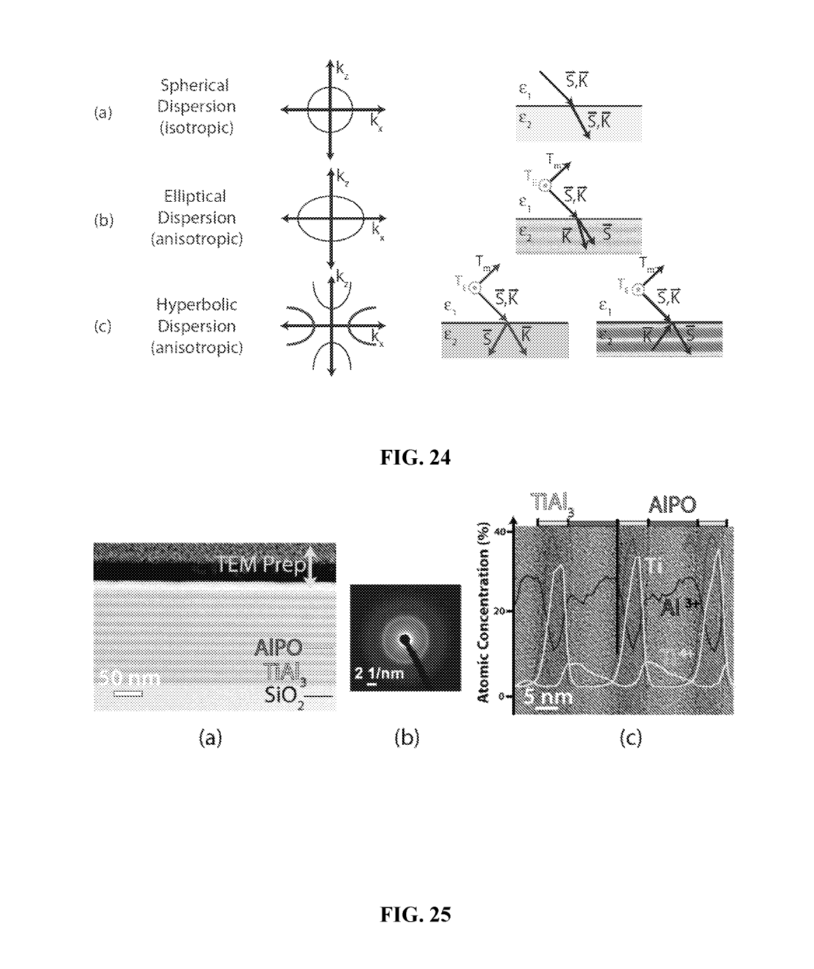

The mathematics describing an anisotropic material possessing two distinct dielectric responses, ∈_{z} and ∈_{xy}, allow for three distinct dispersion effects based on the polarity of ∈_{z} and ∈_{xy}. FIG. 24(b) illustrates anisotropic, elliptical dispersion which occurs when both ∈_{z} and ∈_{xy} are positive. Anisotropic, elliptical dispersion separates K and S as light propagates in the anisotropic material. Anisotropic, hyperbolic dispersion, presented in FIG. 24(c), occurs when ∈_{z} and ∈_{xy} possess opposite signs. Negative refraction occurs when ∈_{z}<0 and ∈_{xy}>0, whereas hyperbolic dispersion with positive refraction occurs when ∈_{z}>0 and ∈_{xy}<0 Anisotropic materials fabricated through this research possess measured reflectance characteristic of anisotropic, elliptical dispersion and hyperbolic dispersion with positive refraction. The images shown in FIGS. 24(b) and (c) are taken from TEM micrographs of the laminate shown in FIGS. 20 and 25, respectively.

### Example

To expand the application of AMMFs from MIM diodes employing amorphous metal electrodes to optical applications, a metallic sputter target made of TiAl₃ was procured. The fabrication of a laminate material was undertaken towards confirming the creation of an optical dispersion engineering materials platform. The fabrication process of the new laminates followed the protocol developed for ZrCuAlNi/AlPO laminates described above.

Amorphous, metallic TiAl₃ layers were deposited via DC magnetron sputtering at 60 W and 3 mTorr using a 20 sccm flow of Ar. The solution precursor for the amorphous oxide, AlPO, used in the laminate was prepared as described above to a 0.1 M concentration of aluminum. The solution precursor was then spin coated onto the TiAl₃ at a speed of 3000 rpm for a duration of 30 s, followed by treatment at 300° C. for 1 min on a hot plate.

FIG. 25 presents the materials analysis of the resulting ten bilayer laminate structure. During the TEM imaging, the extent of the sample was inspected for defects. No defects were revealed, therefore the image in FIG. 25(a) is representative of the laminate across a larger area than shown in the TEM image. FIG. 25(b) shows electron diffraction data, providing evidence of the laminate structure's amorphous nature.

XPS depth profiling was performed through a laminate fabricated concurrently with the laminate imaged via TEM, to generate the overlaid XPS data shown in FIG. 25(c). The initial analysis of the XPS data revealed metal to oxide ratios that were not in alignment with the expected ratios, based on deposition rate studies. Subsequent TEM analysis confirmed that the XPS profiles were dimensionally accurate. The observed reduction of un-oxidized metal thickness was consistent with observations across a variety of amorphous metal/oxide laminates.

Modeling

Effective medium theory predicts spatially averaged values of a laminate structure's dielectric response when the bilayer thickness of the laminate is significantly smaller than the wavelength of incident light. The quasi-static criteria of bilayer thickness has made the fabrication of laminates with anomalous dispersive effects at wavelengths near optical frequencies difficult due to the fabrication issues associated with the deposition of thin, smooth, homogeneous metal films possessing a negative dielectric response. Amorphous metal films, as shown in FIG. 25, have been deposited via DC magnetron sputtering as ultra-smooth, homogenous films with thicknesses less than 5 nm. Solution deposited oxides have been deposited at similar thicknesses, so bilayer dimensions less than 10 nm are presently achievable via amorphous materials. Laminates fabricated with bilayers of 10 nm thickness satisfy the quasi-static condition for light in the deep UV regime. We believe the limit of bilayer thickness accessible through amorphous metal/oxide materials is near 5 nm, which could allow the application of the amorphous material platform to extreme UV wavelengths.

The spatial averaging of distinct, isotropic dielectric responses of amorphous metals and oxides into two anisotropic dielectric responses defines ∈_{z} and ∈_{xy} for T_{M} polarized light as

$$\begin{matrix}{ɛ}_{z} = \frac{{ɛ}_{m} {ɛ}_{d} ( {d}_{m} + {d}_{d} )}{{ɛ}_{m} {d}_{d} + {ɛ}_{d} {d}_{m}} , \\ and & ( 3 ) \\ {ɛ}_{xy} = \frac{{d}_{m} {ɛ}_{m} + {d}_{d} {ɛ}_{d}}{{d}_{m} + {d}_{d}} . & ( 4 )\end{matrix}$$

where z is the direction normal to the layer interface ∈ₘ and dₘ are the dielectric response and film thickness respectively of the amorphous metal layer, and ∈_{d} and d_{d} are the dielectric response and film thickness respectively of the amorphous oxide layer. The material dielectric constants (∈ₘ,∈_{d}) shown above are complex values, making the average anisotropic dielectric response functions complex. In order to find the conditions which must be satisfied for negative refraction the real part of the effective epsilons is considered, which does include all complex material values. Start by introducing the following notation for the real and imaginary material dielectric constants.

∈ₘ=∈_{m′}+i∈_{m″} (5)

∈_{d}=∈_{d′}+i∈_{d″} (6)

Plugging everything into the effective equations above yields

$$\begin{matrix}{ɛ}_{xy} = {d}_{m} ( {ɛ}_{{m}^{′}} + {iɛ}_{{m}^{″}} ) + {d}_{d} ( {ɛ}_{{d}^{′}} + {iɛ}_{{d}^{″}} ) & ( 7 ) \\ {ɛ}_{z} = \frac{( {ɛ}_{{m}^{′}} + {iɛ}_{{m}^{″}} ) ( {ɛ}_{{d}^{′}} + {iɛ}_{{d}^{″}} ) ( {d}_{d} + {d}_{m} )}{( {ɛ}_{{m}^{′}} + {iɛ}_{{m}^{″}} ) {d}_{d} + ( {ɛ}_{{d}^{′}} + {iɛ}_{{d}^{″}} ) {d}_{m}} . & ( 8 )\end{matrix}$$

Again the real part of Eqns. (7, 8) corresponds to the propagating waves in the material system, which for negative refraction to occur Re(∈_{z})<0, and Re(∈_{xy})>0. Without any approximation the real average dielectric constants are

$$\begin{matrix}Re ( {ɛ}_{xy} ) = \frac{{d}_{m} {ɛ}_{{m}^{′}} + {d}_{d} {ɛ}_{{d}^{′}}}{{d}_{d} + {d}_{m}} & ( 9 ) \\ Re ( {ɛ}_{z} ) = \frac{\begin{matrix}( {ɛ}_{{m}^{′}} {ɛ}_{{d}^{′}} - {ɛ}_{{m}^{″}} {ɛ}_{{d}^{″}} ) ( {ɛ}_{{m}^{′}} {d}_{d} + {ɛ}_{{d}^{′}} {d}_{m} ) {d}_{bl} + \\ ( {ɛ}_{{m}^{″}} {ɛ}_{{d}^{′}} + {ɛ}_{{m}^{′}} {ɛ}_{{d}^{″}} ) ( {ɛ}_{{m}^{″}} {d}_{d} + {ɛ}_{{d}^{″}} {d}_{m} ) {d}_{bl}\end{matrix}}{{( {ɛ}_{{m}^{′}} {d}_{d} + {ɛ}_{{d}^{′}} {d}_{m} )}^{2} + {( {ɛ}_{{m}^{″}} {d}_{d} + {ɛ}_{{d}^{″}} {d}_{m} )}^{2}} & ( 10 )\end{matrix}$$

where d_{bl} is the bilayer thickness d_{bl}=d_{d}+dₘ. Eqn. (9) is quite easy to deal with, by inspection we can say that the ∈_{xy} condition for negative refraction is,

$$Re ( {ɛ}_{xy} ) > 0 \\ when \\ {d}_{m} {ɛ}_{{m}^{′}} > - {d}_{d} {ɛ}_{{d}^{′}} \\ or equivalently \\ \frac{- {ɛ}_{{m}^{′}} {d}_{m}}{{ɛ}_{{d}^{′}} {d}_{d}} < 1. \qquad ( 11 )$$

Note that ∈_{m′} in Eqns. (10,11) is negative, and all other constants are positive. Using some algebra Eqn. (10) can be reduced to find the ∈_{z} condition for negative refraction.

$$Re ( {ɛ}_{z} ) < 0 \\ when \\ {ɛ}_{{m}^{′}} {d}_{m} ( {ɛ}_{{d}^{′}}^{2} + {ɛ}_{{d}^{″}}^{2} ) < - {ɛ}_{{d}^{′}} {d}_{d} ( {ɛ}_{{m}^{′}}^{2} + {ɛ}_{{m}^{″}}^{2} ) \\ or equivalently \\ \frac{- {ɛ}_{{m}^{′}} {d}_{m} ( {ɛ}_{{d}^{′}}^{2} + {ɛ}_{{d}^{″}}^{2} )}{{ɛ}_{{d}^{′}} {d}_{d} ( {ɛ}_{{m}^{′}}^{2} + {ɛ}_{{m}^{″}}^{2} )} > 1 \qquad ( 12 )$$

In order for true negative refraction to occur, meaning negative refraction of the Poynting vector inside the planar layers, both inequalities in Eqns. (11, 12) must be simultaneously true. Putting everything together yields the following condition for negative refraction.

$$\frac{( {ɛ}_{{m}^{′}}^{2} + {ɛ}_{{m}^{″}}^{2} )}{( {ɛ}_{{d}^{′}}^{2} + {ɛ}_{{d}^{″}}^{2} )} < \frac{- {ɛ}_{{m}^{′}} {d}_{m}}{{ɛ}_{{d}^{′}} {d}_{d}} < 1 \qquad ( 13 )$$

Negative refraction will occur when Eqn. (13) is satisfied.

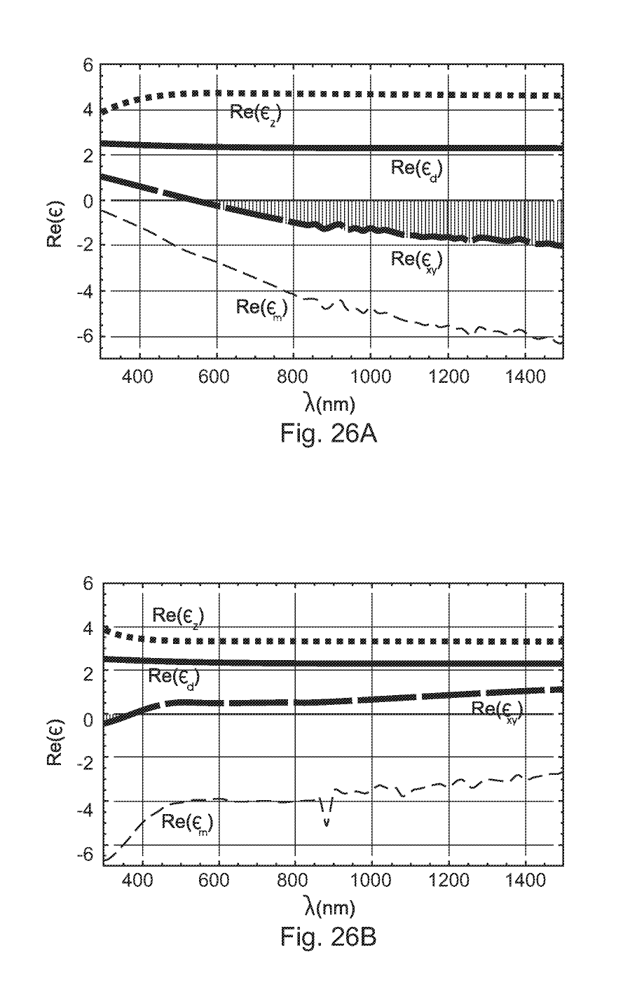

Effective medium theory modeling was performed on ZrCuAlNi/AlPO and TiAl₃/AlPO laminates to calculate the anisotropic dielectric responses ∈_{z} and ∈_{xy}. The modeling employed ellipsometry reflectance data obtained from an optically thick 284 nm bulk ZrCuAlNi sample deposited on an Si/SiO₂ substrate and a 200 nm AlPO sample also deposited onto a Si/SiO₂ substrate. The ellipsometry data was gathered for linearly polarized light of wavelengths between 300 nm and 1500 nm and incident angles between 20° to 80°. The thickness of the layers was determined by analysis of TEM and XPS data, as well as a survey of the measured to modeled error of the reflectance data across all wavelengths and angles. Calculated anisotropic dielectric responses of the laminates as well as the calculated isotropic dielectric responses of the amorphous metals and oxide are presented in FIG. 26. The shaded region above 600 nm in FIG. 26(a) and the region below 350 nm in FIG. 26(b) are frequency ranges where T_{M} polarized incident light exhibits anisotropic hyperbolic dispersion with positive refraction. The remainder of the measured frequencies exhibit anisotropic elliptical dispersion.

The real components of the bulk, isotropic dielectric responses from optically thick ZrCuAlNi and TiAl₃ provide insight into the flexibility of the described amorphous dispersion engineering materials platform. Re(∈) decreases from −1 to −6 for ZrCuAlNi, whereas the dielectric response of TiAl₃ increase from −7 to −3 across the identical frequency range between 300 and 1500 nm. The incongruous dielectric responses of optically thick ZrCuAlNi and TiAl₃ are input into effective medium mathematics (Eq. 3 and 4) to produce two distinct dielectric responses. The resulting anisotropic dielectric response of TiAl₃/AlPO exhibits hyperbolic dispersion below a distinct frequency (i.e. a lowpass filter) while the anisotropic dielectric response of ZrCuAlNi/AlPO exhibits hyperbolic dispersion above a distinct frequency (i.e. a highpass filter). The impact of a laminate metal/dielectric thickness ratio is illustrated in FIG. 26. Equation 4 reveals the magnitude of ∈_{xy} as the arithmetic mean of ∈_{M} and ∈_{d} when a metal/dielectric ratio of 1:1 is employed. ∈_{xy} is seen to be the arithmetic mean of ∈_{M} and ∈_{d} in FIG. 26(a). The ratio of metal to dielectric thickness in the measured TiAl₃/AlPO laminate is lower (i.e. less metal), therefore FIG. 26(b) places ∈_{xy} closer to the dielectric response of AlPO than to the dielectric response of TiAl₃. Simple control of the metal/oxide film thickness ratio enables the precise control of the ∈_{xy} response. Equation 3 contains the multiplication of two complex responses, ∈ₘ and ∈_{d}. The modulation of ∈_{z} is dominated by the imaginary components of the bulk dielectric responses, which requires the selection of amorphous materials based on the observed dielectric loss. Precise control of the anisotropic dielectric response of amorphous laminate structures is accomplished through material selections based on the metal and oxide bulk dielectric responses as well as the ratio of metal to oxide employed in the bilayers, see Eqn. (13).

When fitting experimental reflectance data, the metal to dielectric thickness ratio is critically significant. The mathematics employed in modeling the anisotropic dielectric response of a laminate material assume two, distinct, homogeneous, isotropic, bulk dielectric responses of the metal and oxide layers. Materials analysis indicates that the delineation between the amorphous metal and oxide layers is not abrupt. There are not two distinct layers, but rather a smoothly varying continuum between two distinct dielectric materials. In practice, a detailed mathematical description of a layered structure's spatial atomic densities is not necessary because the layers are much smaller than the wavelength of light (quasistatic). Alternating currents of electrons are routinely described by a root mean square (RMS) value of voltage, even though the actual voltage of the observed electrical signal is rarely at the measured value. Similarly, the structures described herein rarely have stoichiometries equivalent to the measured bulk samples whose dielectric responses are input to effective, anisotropic dielectric response models. Effective medium theory modeling aligns well with all observed measurements. The resulting alignment of continuously changing materials with abrupt mathematical modeling allows us to accept controlled, repeatable, interfacial, interdiffusion.

To directly assess the sensitivity of ellipsometry measurements with respect to amorphous metal/oxide laminates, the measured reflectance data is analyzed. A study of the alignment between modeled and measured reflectance data allows for an evaluation of the sensitivity of reported ellipsometry measurements. The metric through which measurement sensitivity is evaluated is defined as

$$NormalizedError \% = ( {\sum }_{λ = 300 - 1500 nm} \frac{{R}_{meas} - {R}_{model}}{{R}_{meas}} ) \times 100. \qquad ( 14 )$$

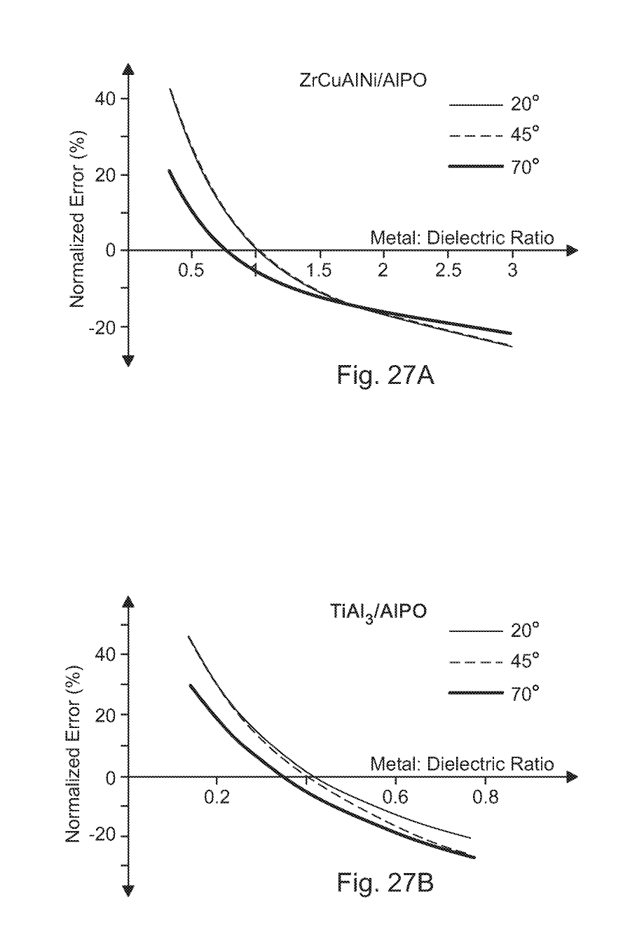

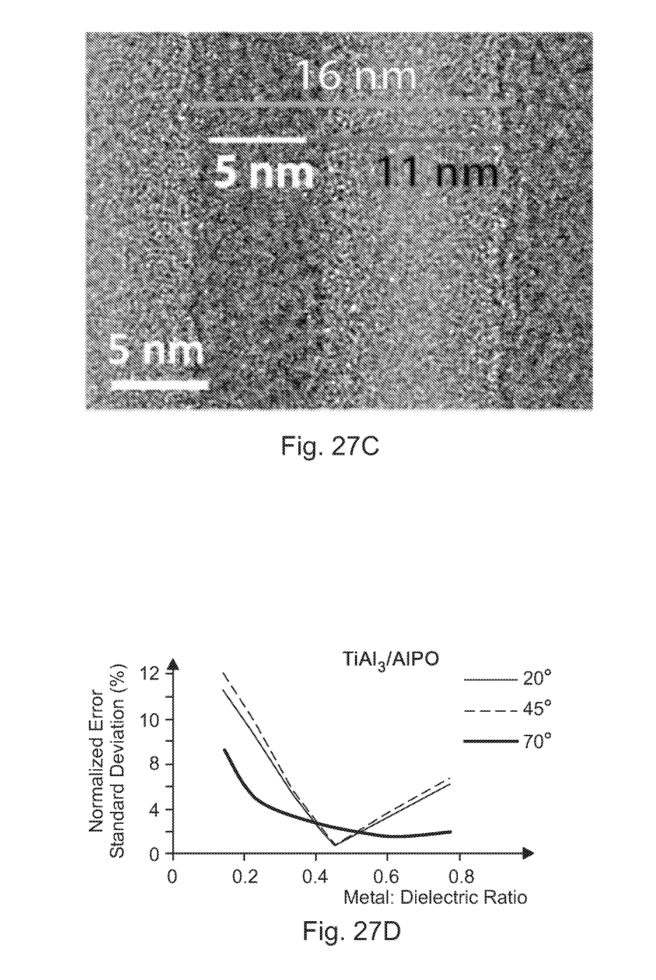

The normalized error metric provides a single value across all wavelengths (300 nm to 1500 nm) at each metal/dielectric ratio and angle of incidence. Normalized error data and materials analysis in support of a quantification of measurement sensitivity are presented in FIG. 27. The metal/dielectric ratio at which the normalized error data is equal to zero is the convergence point of the model and measurement data. FIG. 27 (a) comprises data from a ZrCuAlNi/AlPO laminate, while FIG. 27(b) comprises data from a TiAl₃/AlPO laminate, which are similar to the laminates shown in FIGS. 20 and 26, respectively. Normalized error data from both laminate structures behave similarly with respect to metal/dielectric ratio. For dielectric rich ratios, the modeled reflectance data is of lesser magnitude (less predicted reflectance) than the measurements suggest. The normalized error metric is positive for dielectric rich metal/dielectric ratios. Conversely, for metal rich ratios, the model data predicts more reflectance than measured leading to a negative normalized error. Both conditions are consistent with expected higher reflection from metals and lower reflection from oxide dielectrics.

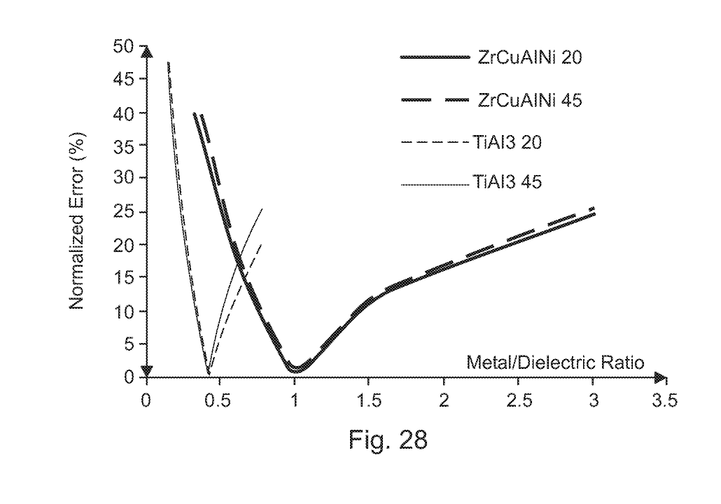

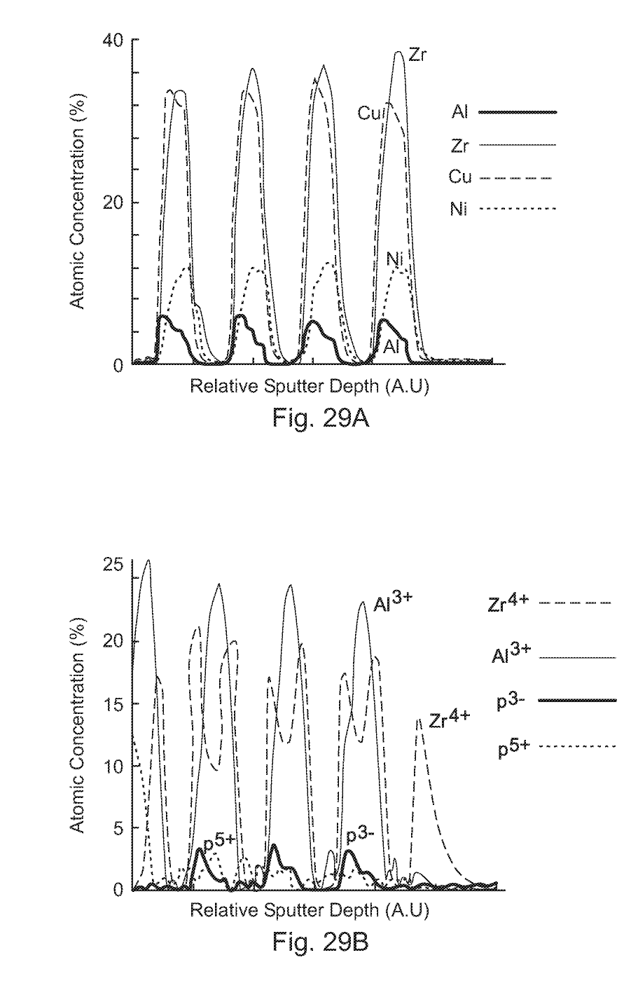

The divergence of normalized error data zero crossings between steep (20° and 45°) and shallow (70°) angles of incidence is geometrically explained. At a shallow angle, the path an incident wave traverses the anisotropic material contains more metal, and hence there is more loss. The model predicts more reflection, which shifts the curve towards a lower metal/dielectric ratio. FIG. 27(c) shows the standard deviation of the summed normalized error for a TiAl₃/AlPO laminate. For comparison the data are also shown along with similar measurements for a ZrCuAlNi sample in FIG. 28. The standard deviation is less than 2% at the metal/dielectric ratio determined via both materials analysis and the normalized error zero point. The TEM micrograph presented in FIG. 27(d) is from a laminate structure shown in FIG. 25. The 16 nm line shows the as deposited bilayer thickness. The lines indicting the metal/dielectric ratio predicted by the zero crossing of the normalized error shown in FIG. 27(b) (4.75:11.75) have been offset slightly to indicate the metal and dielectric areas based on the XPS data shown in FIG. 27(c). The alignment of physical analysis (TEM and XPS) with ellipsometry data (reflectance) suggests that the metal/dielectric ratio may be determined precisely by an analysis of reflectance data.

### Interfacial Chemistries and Properties

Of further potential use in the design and fabrication of the AMMFs and devices of the present disclosure is an understanding of the interfacial solid-state reactions occurring during solution deposition and the more energetic deposition method of sputtering. Multiple experiments were devised in order to observe trends in laminar, solid-state chemical reactions in ultra-thin, ultra-smooth amorphous materials. These experiments define and detail the parameters and thickness limitations inherent to the deposition of this material set and defines the basis of interfacial chemistries occurring at the junctions of ultrathin, ultra-smooth metal and oxide films necessary to properly engineer nanoscale effects by utilizing amorphous materials.

The first set of experiments attempts to define the actual surface depth of chemical reaction at each interface, metal on oxide and oxide on metal, of the laminate. A second set of experiments are devised to provide insight into the chemical mechanism of the measured XPS interfacial chemistry. In these experiments an electropositive metal and a semi-noble metal were deposited in order to test the observed diffusion and interfacial chemical gradients. Another test of the system varies the phosphorus within the amorphous oxide in order to test reagent limitation within the film as a method for controlling a measured interfacial reaction. Sputter power during deposition was investigated in order to determine whether the deposited materials are thermalized in the sputter configuration used throughout the experiment. Finally, amorphous oxide sulfate (as deposited in bulk) systems of 8 hafnium and zirconium are thoroughly investigated to determine whether the trending found in the aluminum phosphate oxide system holds in diverse systems. Interesting behavior was observed in the SOx systems, and further investigation into the measurement was taken.

Initial ZrCuAlNi/AlPO laminates received no additional thermal input after the hotplate treatments of each oxide layer. Electron-diffraction samples were taken from the interdiffusion regions as well as the metal and dielectric layers. All areas provided amorphous patterns to electron diffraction as shown in FIG. 38. Initial EDS profiles showed incongruent diffusion profiles throughout the oxide layer of the laminate, more specifically the profiles detailed the termination of copper and nickel at the interface while zirconium permeated the entire stack. The extreme smoothness and repeatability of the films is obvious from the TEM image, however there are also shaded areas of the AlPO film near the interfaces indicating surface chemistry is taking place at each junction. Sputter-accompanied XPS depth profiling was used to investigate the cross-sectional compositions of the stacks, and the oxidation states of the components to determine the makeup of the interfacial regimes.

While the TEM images in FIG. 38 show smooth, continuos layers, they are not indicative of what is occurring over a large scale. The XPS depth profiles cover a large sample area of 9 mm², and the fact that nanometer-scale resolution is possible over such a large spot size is indicative of exactly how incredibly uniform the films are. Generally, crystalline roughness makes such highly spacially-resolved interfacial XPS depth profiles of crystalline metals films difficult to deconvolute; however, our method of utilizing surface tension and amorphousness to planarize these structures allows for extremely long-range laminated order in the planar dimensions while maintaining incredibly-thin vertical dimensions.

The XPS depth profiles presented in FIG. 29 also show evidence of differing interfacial reactions. The primary reaction involves the oxidation of zirconium metal to Zr(IV) at each interface. This observation is congruent with the TEM measurements that suggest that “valve” metals in bulk metallic glasses, such as zirconium, oxidize preferentially in the presence of oxidizers. In this system, the mechanisms of the perceived oxidation vary depending on the method of deposition for the given interface.

The amorphous metals were processed under vacuum and argon followed by exposure to atmosphere in order to carry out the solution deposition. During the exposure to the ambient environment, a native oxidation of the zirconium component of the amorphous metallic thin film occurred. During solution processing with AlPO solutions, the amorphous metal film was exposed to some small concentration of nitric acid which has been shown to oxidatively etch similar amorphous metals. It has been shown that a native oxide of consistent thickness is present on the ZrCuAlNi thin films whether or not the surface has been exposed to the nitric acid, therefore it can be shown that the primary source of this native oxide is exposure to air during the transfer of the samples through ambient conditions. Each laminate profile shows approximately 2 nm of Zr(IV) oxide at the top surface of each ZrCuAlNi film, regardless of the solution deposited. The preferential oxidation of zirconium from the metal reflects the trend in electropositivity of the metals present in the ZrCuAlNi alloy.

The sputtered-on interface of the metal onto the AlPO has most of the novel reduction chemistry measured. Tapering Zr and Al profiles are observed consistently when the ZrCuAlNi film is deposited upon both the aluminum phosphate oxide and the thermally oxidized silicon. In the sputtered-on interface of the metal and the AlPO, phosphide species are consistently observed, and trace amounts are observed in the lower interface. It is important to note that these phosphide species are not detected in AlPO samples without metal deposited atop them. The following reactions are proposed for the observed phosphide at the interface:

2Zr⁰+PO₄³⁻→2ZrO₂+P³⁻ (15)

8Al⁰+3PO₄³⁻→4Al₂O₃+3P³⁻ (16)

The phosphide was consistently measured at the sputtered-on interfaces within this material set in multiple experiments. Further investigation into the origin and control of the phosphide formation was undertaken, as were experiments into the observed general-chemistry phenomena causing the reaction. It is important to note that little migration of the copper and nickel was measured, demonstrating that the trend of electropositivity within the metals contained in the ZrCuAlNi AMMF has the largest effect on reaction and subsequent migration into the oxide films. It is important to note that it is not probable that all of the oxidized zirconium and aluminum are present due to phosphide reduction. The vast majority of the metal is likely reducing water present in the solution-deposited oxides to become oxidized as shown in equation 17. The oxides used in this study both reported to contain reasonable amounts of water at the processing temperatures used.

Zr⁰+2H₂O→ZrO₂+2H₂ (17)

Metallic Modulation of Reaction at Sputtered-on Interfaces

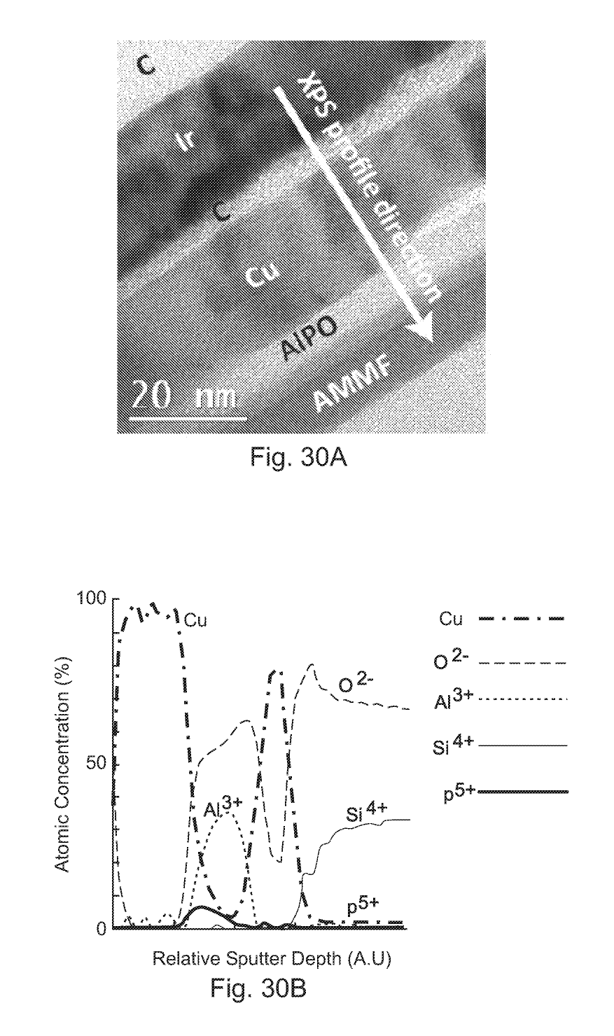

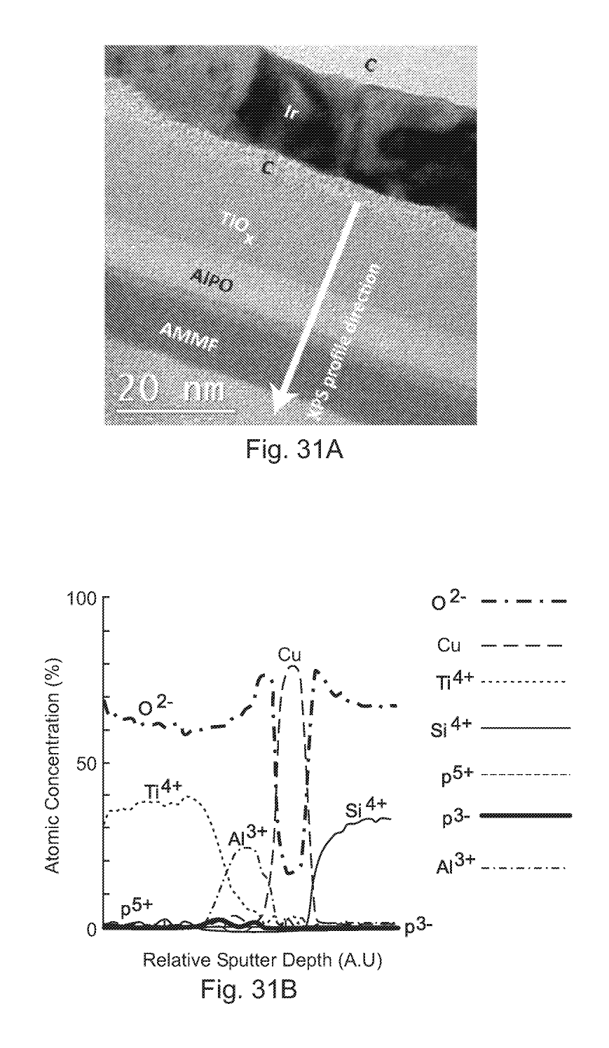

Both copper and titanium metals were RF-magnetron sputtered onto the amorphous AlPO films to test the effects of the electropositivity of the sputtered-on metal in the formation of phosphide at the top interface. Titanium was used because of its greater availability, and similar oxidation chemistry to zirconium. Copper was investigated because it is a cheap noble metal and had shown little migration and oxidation in the initial investigations of the laminated structures. The difference in oxygen affinity between the two metals is clearly illustrated in the TEM images and XPS profiles provided in FIGS. 31 and 30. The TEM image in FIG. 30 displays a crystalline, metallic top film of copper while the titanium pictured in FIG. 31 produces an low-density oxide when exposed to atmosphere. The titanium shows a propensity toward the measurement of phosphide in the sputtered-on surface while the copper shows no ability to complete the reduction of phosphorus. The trend illustrates the spontaneity of the respective electrochemical cells in acidic solution, with Cu|Cu²⁺∥P|P³⁻ being unfavorable and Ti|Ti⁴⁺∥P|P³⁻ being favorable.

Effects of Adjusting Sputtering Power

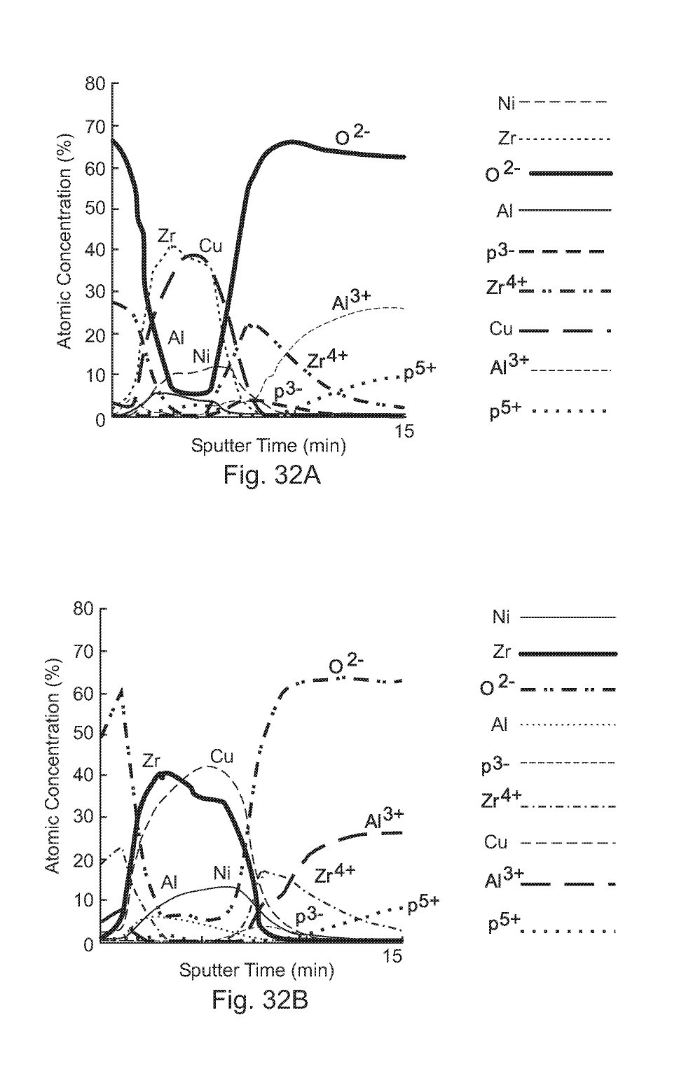

Sputter power was adjusted between 30 and 60 W on the three-inch ZrCuNiAl target to measure the dependence of the system on sputter power. Simple, single-bilayer structures were constructed on thermally oxidized silicon with thick, high-temperature-annealed, 800° C. for 1 hour, AlPO bases and top coats of ZrCuAlNi amorphous metal sputtered at the listed energies. This test confirmed that sputter power can be adjusted over a wide range and still produce consistent, amorphous metallic films from the same target. FIG. 32 shows that no statistically discernable differences in phosphide or Zr⁴⁺ concentrations were measured between the two powers, while the elemental composition of the amorphous metal remained consistent with previous samples. This observation is consistent with the thermalization of sputtered-metallic species expected from the employed deposition pressure and target to substrate distance. Being that the sputter power determines deposition rate of the amorphous metal, this work shows that sputter-deposition time can be easily adjusted without ill effect on this system.

Effects of Adjusting Phosphate Concentration in AlPO

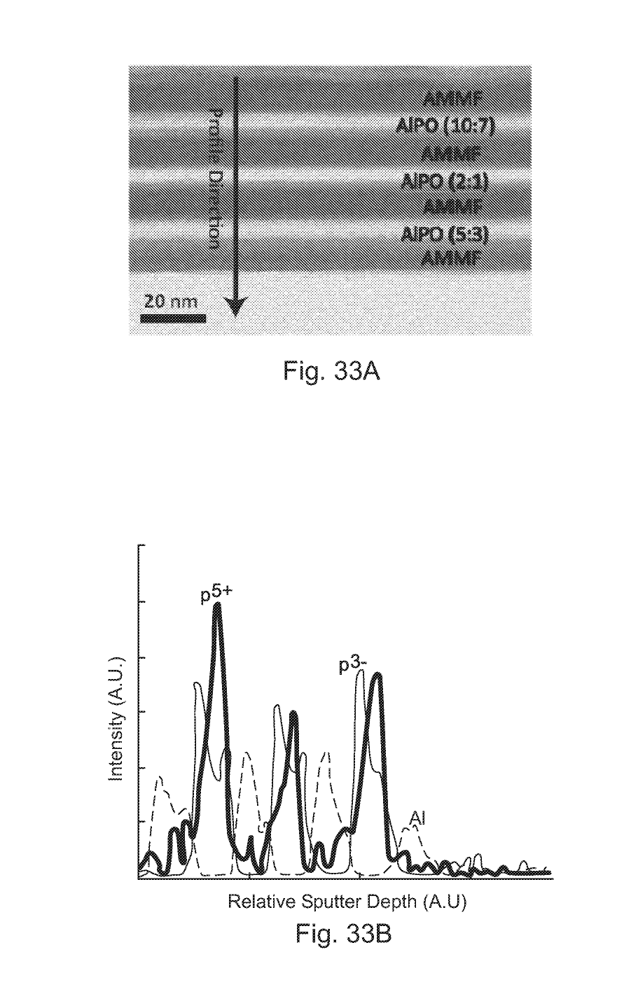

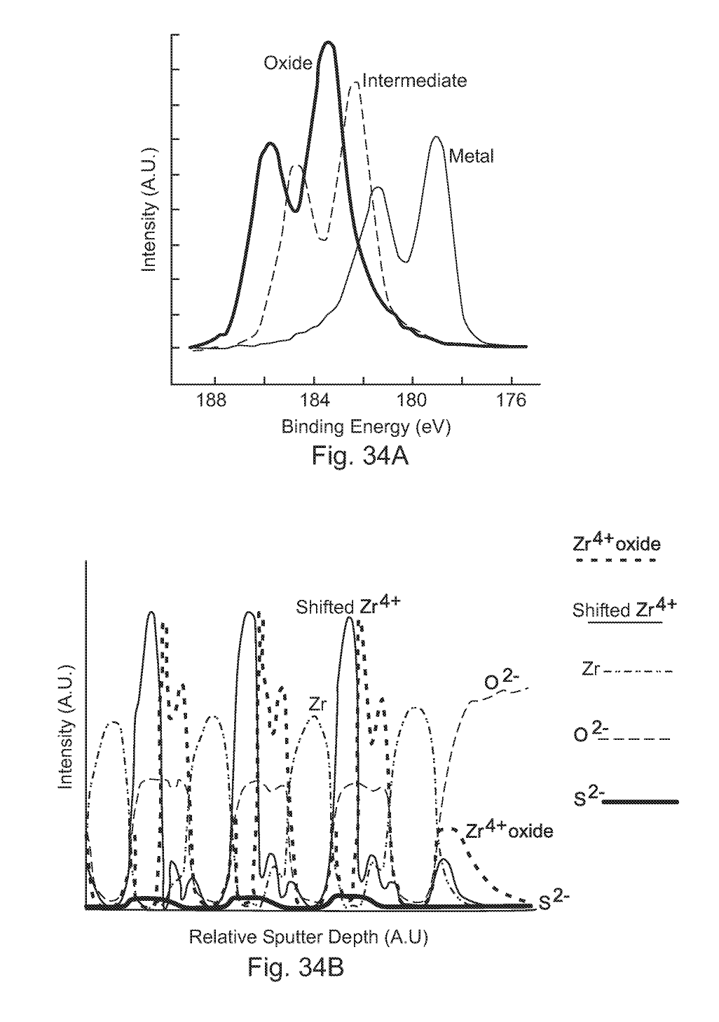

A laminate was constructed in order to study the effect of the AlPO's surface-concentration of phosphorus on the formation of phosphide. The laminate pictured in FIG. 33 was fabricated with three AlPO layers of differing Al:P ratios. The stoichiometric Al:P ratios in the AlPO were arranged from the bottom of the laminate structure to be 5:3, 2:1 and 10:7 respectively. The AMMF layers of ZrCuAlNi were consistently kept to 10 nm with standard deposition energy and gas flows.

The image in FIG. 33 clearly illustrates that a difference in initial phosphate concentration of the solution is carried over into the composition of the laminate. The phosphate intensity corresponds directly to phosphate concentrations in the initial solution and subsequent film. The measured phosphide intensities vary little between the bilayers with Al:P=5:3 and 10:7, while significantly less phosphide is observed when Al:P=2:1. More exploration is needed to determine if this is an indication of a zirconium-limited reduction of the phosphorus at the interface, but initial studies indicate this to be a valid hypothesis.

### Investigation of Varied Dielectrics

Zirconium oxide sulfate and hafnium oxide sulfate solutions were used to produce laminates with ZrCuAlNi in order to test more diverse interfacial-reaction chemistries. Initial bulk measurements were not undertaken because of the degree to which the literature has described the system. It was hypothesized that if the Zirconium in the ZrCuAlNi-AMMF is capable of reducing phosphate species, that the more favorable reduction of sulfur should occur in both sulfur-containing systems. The Zirconium oxide sulfate (ZircSOx) solution also allows further probing of the involvement of Le Chatelier's Principle on these reactions by having a concentration of Zr(IV) already present in the films.

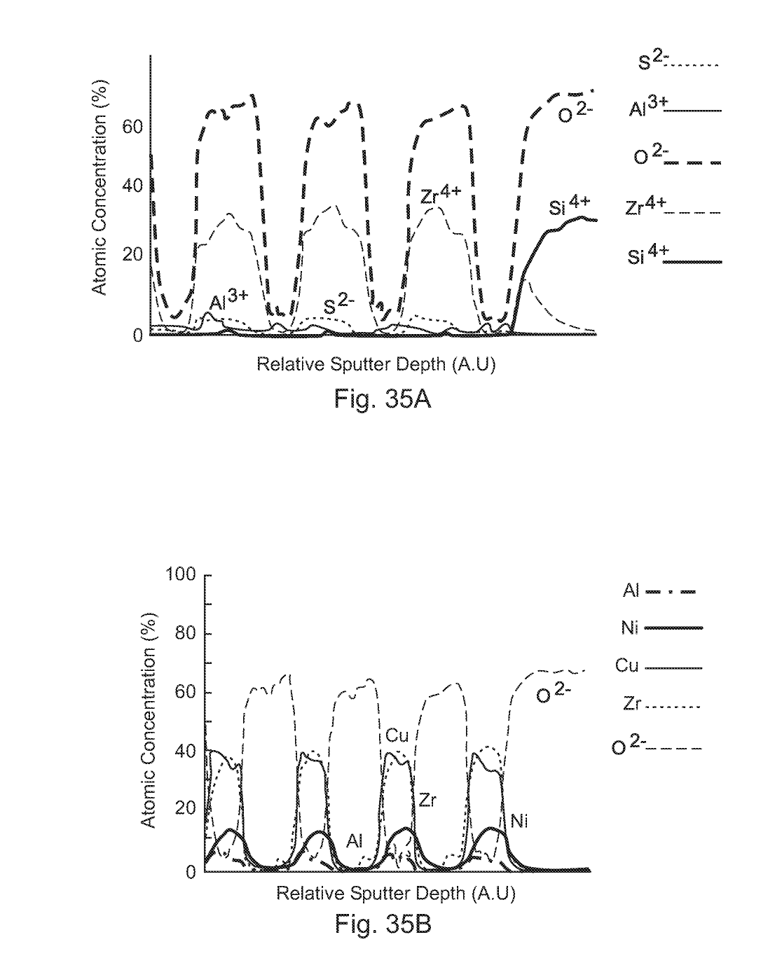

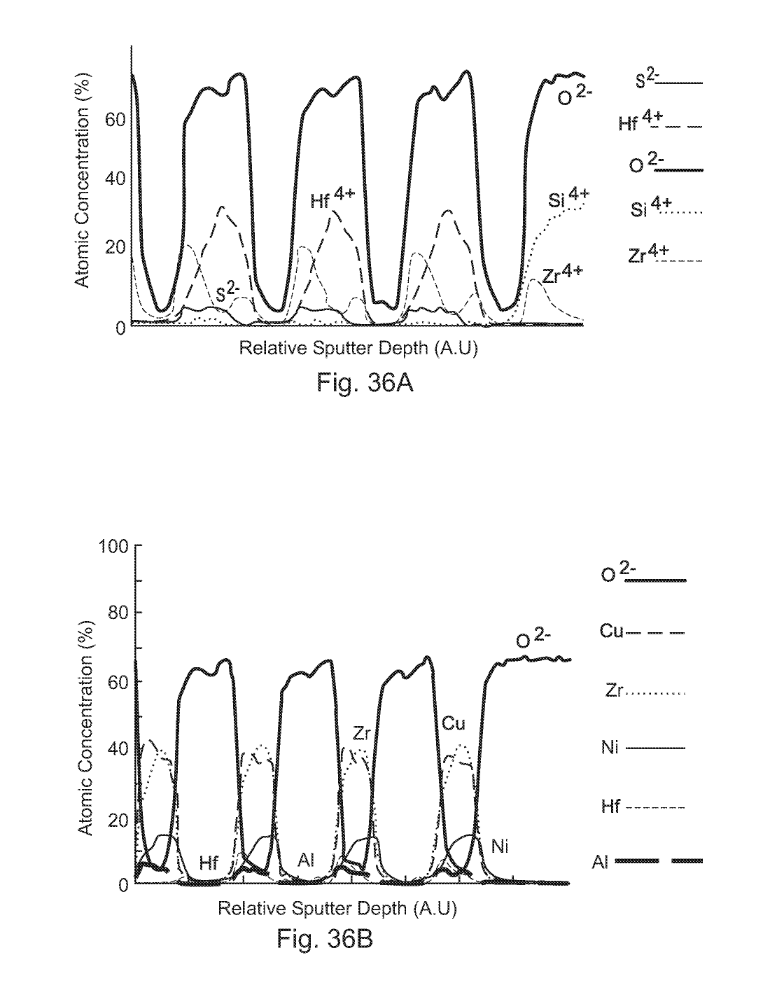

Photoelectron binding-energy evaluations presented in FIG. 34 show a zirconium state between that of the oxide and the metal. It is hypothesized that these photoelectrons correspond to a sulfur-coordinated zirconium because XPS depth profiles presented in FIG. 35 only show sulfide peaks for the sulfur present in the films. FIG. 35 presents a TEM micrograph of a ZircSOx/ZrCuAlNi AMMF laminate with an overlaid XPS spectrum of O²⁻, Si⁴⁺, S²⁻ and Zr⁴⁺. Domain formation is observed in the middle section of the ZircSOx film. This domain growth corresponds to a drop in oxide concentration at the center of the dielectric. Maximum sulfide concentrations are observed in the middle of the ZircSOx layer. It is difficult to know how far the oxygen content decreases in the center due to the extremely-small, lateral feature sizes involved in the measurement. Here is another area where less ablative sputtering techniques may prove useful in defining the species present in nano-structured laminates.

The TEM micrograph shown in FIG. 26 illustrates clear segregation of the heavier atomic species to the center of the HafSOx layer, as well as early domain formation in the middle section of the HafSOx film. The domain growth corresponds to a drop in oxide concentration at the center of the dielectric as with the previous ZircSOx laminate. Maximum sulfide concentrations are measured in the middle of the HafSOx layer, which is completely congruent with sulfide measurements from the ZircSOx laminate.

A small amount of the Hf⁴⁺ is measured as reduced to metal as well as displaced into the AMMF layers as an artifact of sputter reduction. Further XPS depth profiles of 100-nm ZircSOx and HafSOx films deposited on thermally oxidized silicon and heated to 300° C. were also undertaken to check for measurement of sulfide in the films without a metal top layer. Finally, a crystal of copper sulfate was investigated as a reference point for the behavior of a conventional sulfate.

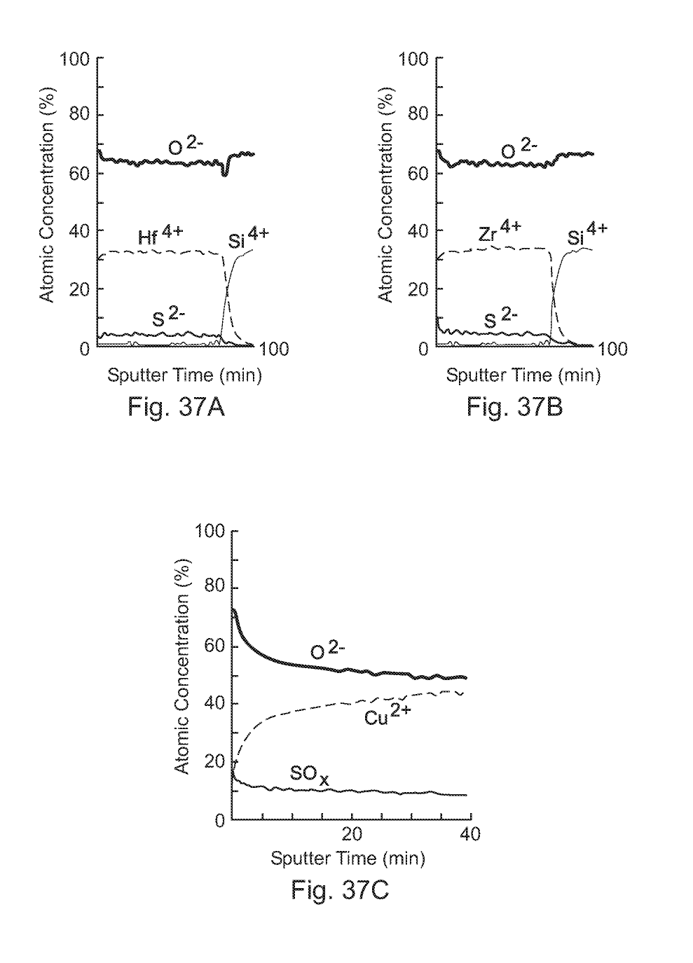

The hafnium and zirconium-based samples without amorphous metal in FIG. 37 show the great majority of sulfur to be present as sulfide; however, sulfur concentrations are found to be similar to those measured by microprobe analysis on doped-HafSOx systems. Being that HafSOx and ZircSOx are solution processed from highlyoxidizing, aqueous solutions containing all sulfur as sulfuric acid, it was initially hypothesized that the sulfide measured in the HafSOx and ZircSOx systems was an effect of the argon-sputtering process used in the depth profile because sulfur has also been shown to reduce from sulfonate to thiol species under 0.2 keV Ar⁺ sputtering in organic styrenes. Sulfate species are easily identifiable in the copper system meaning that the copper system does not participate in the novel chemistry occurring in either the measurement or the HafSOx and ZircSOx systems.

### Anisotropic Thermal Conductivity

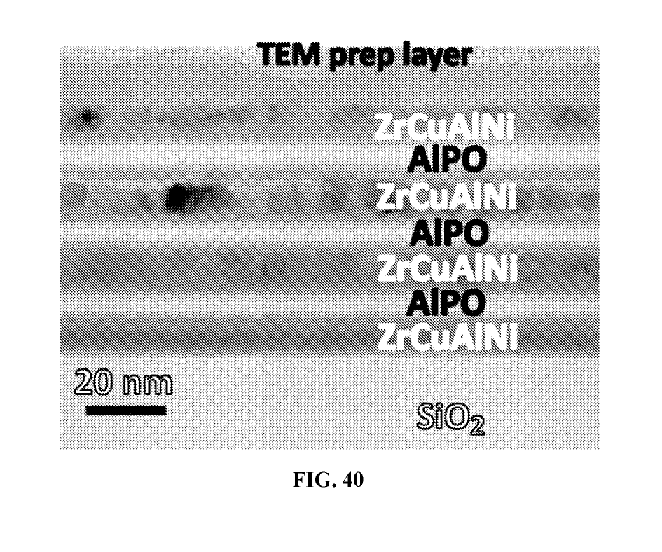

Selection of metal and oxide layers with differing crystallization temperatures offers the ability to alter the thermal conductivity of individual layers. FIG. 40 illustrates the selective crystallization of ZrCuAlNi layers while leaving the AlPO layers amorphous. The thermal conductivity of the now polycrystalline metal layers will be significantly higher than the thermal conductivity of the amorphous oxide layers. By varying the thicknesses of the layers, the metamaterial's anisotropic thermal conductivity can be engineered to specific values. Modulation of amorphous metal and amorphous oxide stoichiometries enables further customization of thermal conductivities.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1. An amorphous multi-component metallic nanolaminate metamaterial, comprising a plurality of film layers disposed in continuity with one another and having a first film layer comprising an amorphous multi-component metal and having a second film layer comprising a dielectric.

2. The amorphous multi-component metallic nanolaminate metamaterial according to claim 1, wherein the dielectric constant of the metamaterial comprises a value different from that present in bulk homogenous materials.

3. The amorphous multi-component metallic nanolaminate metamaterial according to claim 1, wherein the thermal conductivity of the metamaterial comprises a value different from that present in bulk homogenous materials.

4. The amorphous multi-component metallic nanolaminate metamaterial according to claim 1, wherein the amorphous metal comprises ZrCuAlNi.

5. The amorphous multi-component metallic nanolaminate metamaterial according to claim 4, wherein the ZrCuAlNi has the composition ZrₓCu_{y}Al_{z}Ni_{w}, where x>30, y>20, z<30, w<30.

6. The amorphous multi-component metallic nanolaminate metamaterial according to claim 1, wherein the amorphous metal comprises TiAl.

7. The amorphous multi-component metallic nanolaminate metamaterial according to claim 6, wherein the TiAl has the composition TiₓY_{y}, where x<60 and y>40.

8. The amorphous multi-component metallic nanolaminate metamaterial according to claim 1, wherein the second film layer comprises an amorphous oxide.

9. The amorphous multi-component metallic nanolaminate metamaterial according to claim 1, wherein the second film layer comprises AlPO.

10. The amorphous multi-component metallic nanolaminate metamaterial according to claim 9, wherein the AlPO has the composition Al₂(PO₄)₂₋ₓO_{3-3x/2}, where 0<x<2.

11. The amorphous multi-component metallic nanolaminate metamaterial according to claim 1, wherein the second film layer comprises ZircSOx.

12. The amorphous multi-component metallic nanolaminate metamaterial according to claim 11, wherein the ZircSox has the composition ZircO₂₋ₓ(SO₄)ₓ, where 0.4<x<1.0.

13. The amorphous multi-component metallic nanolaminate metamaterial according to claim 1, wherein the second film layer comprises HafSOx.

14. The amorphous multi-component metallic nanolaminate metamaterial according to claim 13, wherein the HafSOx has the composition HafO₂₋ₓ(SO₄)ₓ, where 0.4<x<1.0.

15. The amorphous multi-component metallic nanolaminate metamaterial according to claim 1, wherein the amorphous metal comprises at least one element selected from Groups IV, V, VI, X, XI, XII, Al, Mg, Sn, or Zn.

16. The amorphous multi-component metallic nanolaminate metamaterial according to claim 1, wherein the second film layer comprises Al₂O₃, aluminum phosphate, silicon dioxide, a metal halide, calcium fluoride, zirconium oxide, hafnium dioxide, titanium dioxide, SnO₂, ZnO, or combinations thereof.

17. The amorphous multi-component metallic nanolaminate metamaterial according to claim 1, wherein the amorphous metal comprises metallic elements with varying atomic radii causing a deep eutectic point.

18. The amorphous multi-component metallic nanolaminate metamaterial according to claim 1, wherein the first and second layers are disposed in continuity with one another.

19. The amorphous multi-component metallic nanolaminate metamaterial according to claim 1, wherein the plurality of films layers comprises at least 4 pairs of the first and second layers.

20. The amorphous multi-component metallic nanolaminate metamaterial according to claim 1, wherein effective dielectric constant of the plurality of film layers is anisotropic.

21. The amorphous multi-component metallic nanolaminate metamaterial according to claim 1, wherein the effective dielectric constant in the plane of the plurality of layers has the opposite sign to that of the effective dielectric constant perpendicular to the plane of plurality of the layers.

22. The amorphous multi-component metallic nanolaminate metamaterial according to claim 1, wherein the plurality of film layers has a negative index of refraction.

23. The amorphous multi-component metallic nanolaminate metamaterial according to claim 1, wherein the plurality of film layers has a positive index of refraction.

24. The amorphous multi-component metallic nanolaminate metamaterial according to claim 1, wherein the plurality of film layers has a hyperbolic dispersion.

25. The amorphous multi-component metallic nanolaminate metamaterial according to claim 1, wherein the plurality of film layers has an anisotropic thermal conductivity.

26. The amorphous multi-component metallic nanolaminate metamaterial according to claim 25, wherein the thermal conductivity in the plane of the plurality of layers has the opposite sign to that of the thermal conductivity perpendicular to the plane of the plurality of layers.

27. The amorphous multi-component metallic nanolaminate metamaterial according to claim 1, wherein the first film layer has a thickness less than 20 nm.

28. The amorphous multi-component metallic nanolaminate metamaterial according to claim 1, wherein the first and second film layers have a combined thickness of less than 100 nm.

29. The amorphous multi-component metallic nanolaminate metamaterial according to claim 1, wherein the first and second film layers have an interface therebetween which is atomically smooth.

30. The amorphous multi-component metallic nanolaminate metamaterial according to claim 1, wherein the first film layer has a resistivity of at least 100 Ω-cm.

31. (canceled)

32. (canceled)
